(19) United States
(12) Patent Application Publication
(10) Pub. No.: US 2025/0040278 A1
(43) Pub. Date: Jan. 30, 2025

(54) SOLID-STATE IMAGING ELEMENT AND ELECTRONIC DEVICE

(71) Applicant: SONY SEMICONDUCTOR SOLUTIONS CORPORATION, KANAGAWA (JP)

(72) Inventor: RINO TAKAHASHI, KANAGAWA (JP)

(21) Appl. No.: 18/716,338

(22) PCT Filed: Oct. 18, 2022
(86) PCT No.: PCT/JP2022/038761

§ 371 Date: Jun. 4, 2024

(30) Foreign Application Priority Data
Dec. 13, 2021 (JP) 2021-201949

(51) Int. Cl. H01L 27/146; H04N 25/532; H04N 25/63; H04N 25/77

(52) U.S. Cl. CPC H01L 27/14623; H01L 27/14621; H01L 27/14643; H04N 25/532; H04N 25/63; H04N 25/77

(57) ABSTRACT

[Problem] A technology is provided that is advantageous in effectively reducing PLS noise and suppressing obstruction of the flow of electrons in a photoelectric conversion portion.

[Means of Solution] The pixel separation portion is provided with a first light-shielding member that is disposed closer to the color filter than the charge transfer portion is. The first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction. At least a part of a portion of the pixel separation portion facing the second light-shielding portion in the width direction is disposed at a position that does not overlap with the first-type color filter but overlaps with the second-type color filter when viewed from above in the depth direction.

### TECHNICAL FIELD

The present disclosure relates to a solid-state imaging element and an electronic device.

### BACKGROUND ART

For solid-state imaging elements such as backside-illuminated complementary metal oxide semiconductor (CMOS) image sensors, a global shutter scheme is widely used, which is advantageous for dynamic imaging.

In a solid-state imaging element that uses a global shutter scheme, charges (pixel signals) generated by photoelectric conversion for each pixel are sent to a charge holding portion via a gate electrode and accumulated in the charge holding portion.

In a solid-state imaging element having such a configuration, parasitic light sensitivity (PLS) noise caused by light passing through a photoelectric conversion portion and entering the gate electrode is accumulated in the charge holding portion, which may cause deterioration in the quality of captured images.

In order to reduce PLS noise, the imaging devices disclosed in PTL 1 and PTL 2 include locally-arranged light-shielding portions in a semiconductor substrate to prevent leakage of light that is not originally expected.

### CITATION LIST

### Patent Literature

### [PTL 1]

JP 2018-148039A

### [PTL 2]

WO 2021/112098

### SUMMARY

### Technical Problem

In a case where light-shielding portions are processed and formed on a semiconductor substrate to reduce the above-described PLS noise, there is a concern that dark current characteristics may deteriorate due to damage applied to the semiconductor substrate during processing and forming. In order to suppress such deterioration of dark current characteristics, it is effective to generate P-type crystals by implanting impurities around the processed portion of the semiconductor substrate.

However, a P-type impurity implanted region formed in this way results in a locally reduced cross-sectional area of photoelectric conversion portion, which may prevent electrons from smoothly flowing in the photoelectric conversion portion and thus reduce the pixel sensitivity.

The present disclosure has been made in view of the above-described circumstances, and provides a technology that is advantageous in effectively reducing PLS noise and suppressing obstruction of the flow of electrons in a photoelectric conversion portion.

### Solution to Problem

One aspect of the present disclosure relates to a solid-state imaging element including: a substrate with a plurality of pixels arranged; and a color filter that covers the substrate, wherein each of the plurality of pixels includes a photoelectric conversion portion that is partitioned by a pixel separation portion, a charge holding portion that holds a charge, and a charge transfer portion that transfers a charge generated in the photoelectric conversion portion to the charge holding portion, the color filter includes a first-type color filter portion, and a second-type color filter portion that transmits light in a wavelength range on a shorter wavelength side than a light transmission wavelength range of the first-type color filter portion, the plurality of pixels include a first-type pixel to which the first-type color filter portion is assigned, and a second-type pixel to which the second-type color filter portion is assigned, the pixel separation portion is provided with a first light-shielding member that is disposed closer to the color filter than the charge transfer portion is, the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and at least a part of a portion of the pixel separation portion facing the second light-shielding portion in the width direction is disposed at a position that does not overlap with the first-type color filter but overlaps with the second-type color filter when viewed from above in the depth direction.

The color filter may further include a third-type color filter portion that transmits light in a wavelength range shorter than that of the second-type color filter portion, and the plurality of pixels may further include a third-type pixel to which a third-type color filter portion is assigned.

The first-type color filter portion may be an R color filter portion, and the second-type color filter portion may be a G color filter portion.

The color filter may have a Bayer array.

The color filter may have a Quad-Bayer array.

The first light-shielding member may include a third light-shielding portion that extends in the depth direction, and a fourth light-shielding portion that extends in the width direction and is disposed at a position that partially overlaps with both of the photoelectric conversion portion of the first-type pixel and the photoelectric conversion portion of the second-type pixel when viewed from above in the depth direction, and the fourth light-shielding portion may be disposed at a different position from the second light-shielding portion in the depth direction and between the photoelectric conversion portion of the first-type pixel and the photoelectric conversion portion of the second-type pixel.

The solid-state imaging element may include a second light-shielding member that covers the charge holding portion.

The solid-state imaging element may include a third light-shielding member that is disposed closer to the color filter than the charge transfer portion is and extends in the depth direction between the photoelectric conversion portion of the first-type pixel and the photoelectric conversion portion of the second-type pixel.

A distance in the depth direction between a light incident surface of the photoelectric conversion portion on which light from the color filter is incident and the charge transfer portion may be 5.0 μm or more.

Another aspect of the present disclosure relates to an electronic device including a solid-state imaging element, wherein the solid-state imaging element includes a substrate with a plurality of pixels arranged, and a color filter that covers the substrate, each of the plurality of pixels includes a photoelectric conversion portion that is partitioned by a pixel separation portion, a charge holding portion that holds a charge, a charge transfer portion that transfers a charge generated in the photoelectric conversion portion to the charge holding portion, and a first light-shielding member that is provided in the pixel separation portion and is disposed closer to the color filter than the charge transfer portion is, the color filter includes a first-type color filter portion, and a second-type color filter portion that transmits light in a wavelength range on a shorter wavelength side than a light transmission wavelength range of the first-type color filter portion, the plurality of pixels include a first-type pixel to which the first-type color filter portion is assigned, and a second-type pixel to which the second-type color filter portion is assigned, the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and at least a part of a portion of the pixel separation portion facing the second light-shielding portion in the width direction is disposed at a position that does not overlap with the first-type color filter but overlaps with the second-type color filter when viewed from above in the depth direction.

### BRIEF DESCRIPTION OF DRAWINGS

FIG. 1 is a block diagram illustrating a schematic configuration of an example of an imaging device.

FIG. 2 is an equivalent circuit diagram of a sensor pixel and a readout circuit.

FIG. 3 is a cross-sectional view illustrating a schematic configuration of a part of an example of a sensor pixel in a pixel array unit.

FIG. 4 is an enlarged cross-sectional view schematically illustrating an example of a solid-state imaging element (especially effective pixel region) according to a first embodiment.

FIG. 5 is an enlarged top view of the solid-state imaging element illustrated in FIG. 4, schematically illustrating an arrangement example of a color filter (R filter portions, G filter portions, and B filter portions), a pixel separation portion, vertical electrodes, and second light-shielding portions.

FIG. 6 is an enlarged top view of the solid-state imaging element illustrated in FIG. 4, schematically illustrating an arrangement example of a photoelectric conversion portion, the pixel separation portion, the vertical electrodes, and the second light-shielding portions, with the color filter omitted.

FIG. 7 is an enlarged cross-sectional view schematically illustrating an example of a solid-state imaging element according to a second embodiment.

FIG. 8 is an enlarged top view of the solid-state imaging element illustrated in FIG. 7, schematically illustrating an arrangement example of a color filter, a pixel separation portion, vertical electrodes, and fourth light-shielding portions.

FIG. 9 is an enlarged top view of the solid-state imaging element illustrated in FIG. 7, schematically illustrating an arrangement example of the color filter, the pixel separation portion, the vertical electrodes, and second light-shielding portions.

FIG. 10 is an enlarged cross-sectional view schematically illustrating an example of a solid-state imaging element according to a third embodiment.

FIG. 11 is an enlarged top view of the solid-state imaging element illustrated in FIG. 10, schematically illustrating an arrangement example of a color filter, a pixel separation portion, vertical electrodes, and fourth light-shielding portions.

FIG. 12 is an enlarged top view of the solid-state imaging element illustrated in FIG. 10, schematically illustrating an arrangement example of the color filter, the pixel separation portion, the vertical electrodes, and second light-shielding portions.

FIG. 13 is an enlarged cross-sectional view schematically illustrating an example of a solid-state imaging element according to a fourth embodiment.

FIG. 14 is an enlarged top view of the solid-state imaging element illustrated in FIG. 13, schematically illustrating an arrangement example of a color filter, a pixel separation portion, vertical electrodes, and second light-shielding portions.

FIG. 15 is an enlarged cross-sectional view schematically illustrating an example of a solid-state imaging element according to a fifth embodiment.

FIG. 16 is an enlarged top view of the solid-state imaging element illustrated in FIG. 15, schematically illustrating an arrangement example of a color filter, a pixel separation portion, vertical electrodes, and fourth light-shielding portions.

FIG. 17 is an enlarged top view of the solid-state imaging element illustrated in FIG. 15, schematically illustrating an arrangement example of the color filter, the pixel separation portion, the vertical electrodes, and second light-shielding portions.

FIG. 18 is an enlarged cross-sectional view schematically illustrating an example of a solid-state imaging element according to a sixth embodiment.

FIG. 19 is an enlarged top view of the solid-state imaging element illustrated in FIG. 18, schematically illustrating an arrangement example of a color filter, a pixel separation portion, vertical electrodes, and fourth light-shielding portions.

FIG. 20 is an enlarged top view of the solid-state imaging element illustrated in FIG. 18, schematically illustrating an arrangement example of the color filter, the pixel separation portion, the vertical electrodes, and second light-shielding portions.

FIG. 21A is a cross-sectional view illustrating an example of a method of manufacturing a solid-state imaging element (particularly FEOL).

FIG. 21B is a cross-sectional view illustrating the example of the method of manufacturing the solid-state imaging element (particularly FEOL).

FIG. 21C is a cross-sectional view illustrating the example of the method of manufacturing the solid-state imaging element (particularly FEOL).

FIG. 21D is a cross-sectional view illustrating the example of the method of manufacturing the solid-state imaging element (particularly FEOL).

FIG. 21E is a cross-sectional view illustrating the example of the method of manufacturing the solid-state imaging element (particularly FEOL).

FIG. 22A is a cross-sectional view illustrating an example of the method of manufacturing the solid-state imaging element (particularly BEOL).

FIG. 22B is a cross-sectional view illustrating the example of the method of manufacturing the solid-state imaging element (particularly BEOL).

FIG. 22C is a cross-sectional view illustrating the example of the method of manufacturing the solid-state imaging element (particularly BEOL).

FIG. 22D is a cross-sectional view illustrating the example of the method of manufacturing the solid-state imaging element (particularly BEOL).

FIG. 22E is a cross-sectional view illustrating the example of the method of manufacturing the solid-state imaging element (particularly BEOL).

FIG. 22F is a cross-sectional view illustrating the example of the method of manufacturing the solid-state imaging element (particularly BEOL).

FIG. 22G is a cross-sectional view illustrating the example of the method of manufacturing the solid-state imaging element (particularly BEOL).

FIG. 22H is a cross-sectional view illustrating the example of the method of manufacturing the solid-state imaging element (particularly BEOL).

FIG. 23A is a cross-sectional view illustrating an example of a method of manufacturing a first light-shielding portion and a second light-shielding portion.

FIG. 23B is a cross-sectional view illustrating the example of the method of manufacturing the first light-shielding portion and the second light-shielding portion.

FIG. 23C is a cross-sectional view illustrating the example of the method of manufacturing the first light-shielding portion and the second light-shielding portion.

FIG. 23D is a cross-sectional view illustrating the example of the method of manufacturing the first light-shielding portion and the second light-shielding portion.

FIG. 23E is a cross-sectional view illustrating the example of the method of manufacturing the first light-shielding portion and the second light-shielding portion.

FIG. 23F is a cross-sectional view illustrating the example of the method of manufacturing the first light-shielding portion and the second light-shielding portion.

FIG. 23G is a cross-sectional view illustrating the example of the method of manufacturing the first light-shielding portion and the second light-shielding portion.

FIG. 24 is a block diagram illustrating a configuration example of an imaging device as an electronic device.

FIG. 25 is a block diagram illustrating an example of a schematic configuration of a vehicle control system.

FIG. 26 is an explanatory diagram illustrating an example of installation positions of vehicle exterior information detection units and imaging units.

FIG. 27 is a diagram illustrating an example of a schematic configuration of an endoscopic surgery system.

FIG. 28 is a block diagram illustrating an example of functional configurations of a camera head and a CCU.

### DESCRIPTION OF EMBODIMENTS

Typical embodiments of the present disclosure will be described with reference to the drawings.

An imaging device (an electronic device) described below includes a backside-illuminated solid-state imaging element (an image sensor) such as a CMOS image sensor that uses a global shutter scheme, and receives light from a subject on a pixel-by-pixel basis for photoelectric conversion to generate a pixel signal that is an electrical signal.

According to the global shutter scheme, the start and end of exposure of all pixels are at the same time. All pixels as used herein refer to all pixels that form an effective image, excluding dummy pixels and the like that do not contribute to image formation. The start and end of exposure need not necessarily be exactly at the same time for all pixels as long as image distortion and exposure time differences are small enough to cause no problems. For example, the global shutter scheme also includes an operation in which simultaneous exposure for every two or more rows (such as several tens of rows) is repeated while being shifted by the two or more rows in the row direction. In addition, the global shutter scheme also includes an operation of simultaneous exposure for only a partial pixel region.

The backside-illuminated solid-state imaging element is a solid-state imaging element in which a photoelectric conversion portion such as a photodiode that receives light from a subject and converts the light into an electric signal is disposed for each pixel between a light-receiving surface on which light from the subject is incident and a wiring layer in which wires for a transistor or the like that drives the pixel are arranged. The present disclosure may be applicable to solid-state imaging elements using imaging methods other than the CMOS solid-state imaging element.

### [Block Configuration of Imaging Device 101]

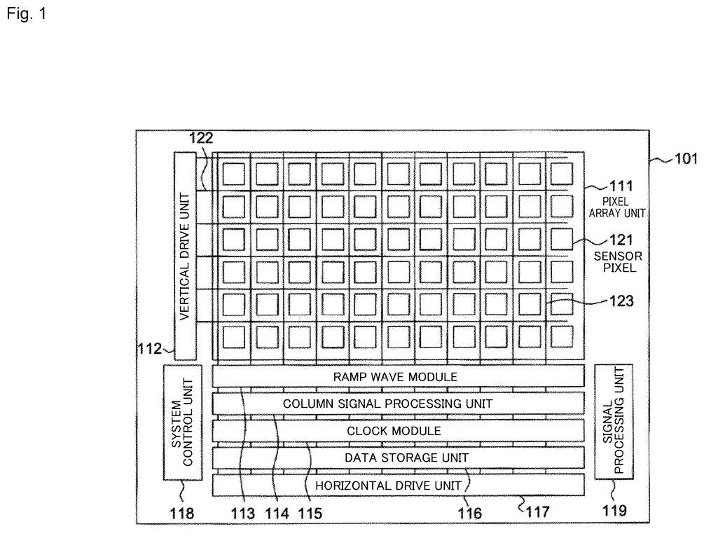

FIG. 1 is a block diagram illustrating a schematic configuration of an example of an imaging device 101. Although the imaging device 101 in FIG. 1 is accurately a solid-state imaging device, which is formed on a semiconductor substrate, the imaging device 101 will simply be referred to as the imaging device 101 below.

The imaging device 101 in FIG. 1 includes a pixel array unit 111 in which a plurality of sensor pixels 121 that perform photoelectric conversion are arranged in a matrix shape, that is, a two-dimensional planar shape. The sensor pixels 121 correspond to one specific example of the “pixels” according to the present disclosure. A pixel signal resulting from photoelectric conversion in the pixel array unit 111 is read out through a readout circuit.

The imaging device 101 includes, for example, the pixel array unit 111, a vertical drive unit 112, a ramp wave module 113, a column signal processing unit 114, a clock module 115, a data storage unit 116, a horizontal drive unit 117, a system control unit 118, and a signal processing unit 119.

The imaging device 101 is configured by a single or a plurality of semiconductor substrates. For example, the imaging device 101 can have a configuration in which a semiconductor substrate on which the pixel array unit 111 is formed is electrically connected to another semiconductor substrate in which other elements are formed by Cu—Cu bonding or the like. Formed in the other semiconductor substrate as used herein may be, for example, the vertical drive unit 112, the ramp wave module 113, the column signal processing unit 114, the clock module 115, the data storage unit 116, the horizontal drive unit 117, the system control unit 118, the signal processing unit 119, and the like.

The pixel array unit 111 includes a plurality of sensor pixels 121 including photoelectric conversion elements that generate and accumulate a charge in accordance with the amount of incident light. These sensor pixels 121 are arranged in the horizontal direction (row direction) and the vertical direction (column direction) as illustrated in FIG. 1. In the pixel array unit 111, a pixel drive line 122 is wired along the row direction for each pixel row including sensor pixels 121 aligned in one line in the row direction, and a vertical signal line 123 is wired along the column direction for each pixel column including sensor pixels 121 aligned in one line in the column direction.

The vertical drive unit 112 is configured with a shift register, an address decoder, or the like. The vertical drive unit 112 causes all the plurality of sensor pixels 121 in the pixel array unit 111 to be driven at the same time or in units of pixel rows by supplying a signal or the like to each of the plurality of sensor pixels 121 via the plurality of pixel drive lines 122.

The ramp wave module 113 generates a ramp wave signal used for analog/digital (A/D) conversion of the pixel signal and supplies the ramp wave signal to the column signal processing unit 114. The column signal processing unit 114 includes, for example, a shift resister, an address decoder, or the like and performs noise removal processing, correlated double sampling processing, A/D conversion processing, and the like to generate a pixel signal. The column signal processing unit 114 supplies the generated pixel signal to the signal processing unit 119.

The clock module 115 supplies a clock signal for an operation to each component of the imaging device 101.

The horizontal drive unit 117 selects unit circuits of the column signal processing unit 114 corresponding to the pixel columns in order. Through the selective scanning of the horizontal drive unit 117, the pixel signals subjected to the signal processing on each unit circuit in the column signal processing unit 114 are sequentially output to the signal processing unit 119.

The system control unit 118 includes a timing generator or the like that generates various timing signals. The system control unit 118 controls driving of the vertical drive unit 112, the ramp wave module 113, the column signal processing unit 114, the clock module 115, and the horizontal drive unit 117 based on a timing signal generated by the timing generator.

The signal processing unit 119 performs signal processing such as arithmetic processing on the pixel signal supplied from the column signal processing unit 114 while temporarily storing data in the data storage unit 116 as necessary, and outputs an image signal made up of the resulting pixel signals.

### [Circuit Configuration of Readout Circuit 120]

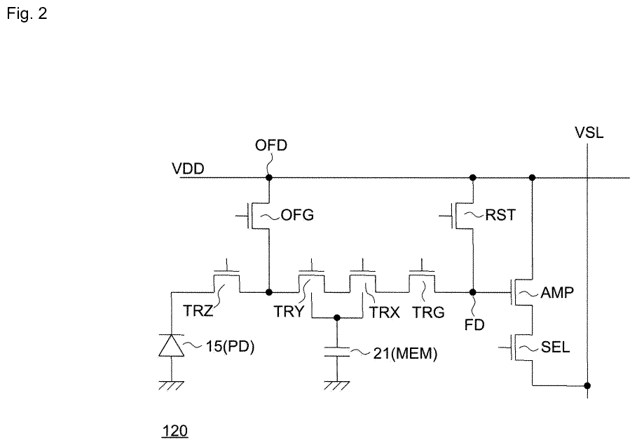

FIG. 2 is an equivalent circuit diagram of the sensor pixel 121 and a readout circuit 120.

The readout circuit 120 illustrated in FIG. 2 includes four transfer transistors TRZ, TRY, TRX, and TRG, a discharge transistor OFG, a reset transistor RST, an amplifier transistor AMP, and a selection transistor SEL. These transistors are N-type MOS transistors. The reset transistor RST, the amplifier transistor AMP, and the selection transistor SEL are formed in a semiconductor substrate different from the semiconductor substrate in which the pixel array unit 111 is disposed.

An example will be mainly described below in which a photodiode PD is used as a photoelectric conversion portion 15. The transfer transistor TRZ is connected to the photodiode PD in the sensor pixel 121, and transfers the charge (a pixel signal) photoelectrically converted by the photodiode PD to the transfer transistor TRY. The transfer transistor TRZ is assumed to be a vertical transistor and has a vertical gate electrode (a vertical electrode 22 described later).

The transfer transistor TRY transfers the charge transferred from the transfer transistor TRZ to the transfer transistor TRX. The transfer transistor TRY and the transfer transistor TRX may be replaced with one transfer transistor. A charge holding portion (MEM) 21 is connected to the transfer transistor TRY and the transfer transistor TRX. The potential of the charge holding portion (MEM) 21 is controlled by a control signal applied to the gate electrodes of the transfer transistor TRY and the transfer transistor TRX. For example, when the transfer transistor TRY and the transfer transistor TRX are turned on, the charge holding portion (MEM) 21 becomes to have a deep potential. When the transfer transistor TRY and the transfer transistor TRX are turned off, the charge holding portion (MEM) 21 becomes to have a shallow potential. For example, when the transfer transistors TRZ, TRY, and TRX are turned on, the charge accumulated in the photodiode PD are transferred to the charge holding portion (MEM) 21 through the transfer transistors TRZ, TRY, and TRX. The drain of the transfer transistor TRX is electrically connected to the source of the transfer transistor TRG, and the gates of the transfer transistors TRY and TRX are connected to a pixel drive line.

The charge holding portion (MEM) 21 is a region that temporarily holds the charge accumulated in the photodiode PD in order to realize a global shutter function. The charge holding portion (MEM) 21 holds the charge transferred from the photodiode PD.

The transfer transistor TRG is connected between the transfer transistor TRX and a floating diffusion FD and transfers the charge held by the charge holding portion (MEM) 21 to the floating diffusion FD in response to a control signal applied to the gate electrode. For example, when the transfer transistor TRX is turned off and the transfer transistor TRG is turned on, the charge held in the charge holding portion (MEM) 21 is transferred to the floating diffusion FD. The drain of the transfer transistor TRG is electrically connected to the floating diffusion FD, and the gate of the transfer transistor TRG is connected to the pixel drive line.

The floating diffusion FD is a floating and diffusion region that temporarily holds the charge output from the photodiode PD through the transfer transistor TRG. The reset transistor RST, for example, is connected to the floating diffusion FD, and a vertical signal line VSL is connected to the floating diffusion FD through the amplifier transistor AMP and the selection transistor SEL.

The discharge transistor OFG initializes (resets) the photodiode PD in response to a control signal applied to the gate electrode. The drain OFD of the discharge transistor OFG is connected to a power source line VDD, and the source thereof is connected between the transfer transistor TRZ and the transfer transistor TRY.

For example, when the transfer transistor TRZ and the discharge transistor OFG are turned on, the potential of the photodiode PD is reset to the potential level of the power source line VDD. In other words, the photodiode PD is initialized. The discharge transistor OFG forms, for example, an overflow path between the transfer transistor TRZ and the power source line VDD, and discharges the charge overflowing from the photodiode PD to the power source line VDD.

The reset transistor RST initializes (resets) each region from the charge holding portion (MEM) 21 to the floating diffusion FD in response to a control signal applied to the gate electrode. The drain of the reset transistor RST is connected to the power source line VDD, and the source thereof is connected to the floating diffusion FD. For example, when the transfer transistor TRG and the reset transistor RST are turned on, the potentials of the charge holding portion (MEM) 21 and the floating diffusion FD are reset to the potential level of power source line VDD. Thus, by turning on the reset transistor RST, the charge holding portion (MEM) 21 and the floating diffusion FD are initialized.

The amplifier transistor AMP has a gate electrode connected to the floating diffusion FD and a drain connected to the power source line VDD and serves as an input unit of a source follower circuit that reads out a charge obtained through photoelectric conversion at the photodiode PD. In other words, the amplifier transistor AMP constitutes a source follower circuit with a constant current source connected to one end of the vertical signal line VSL by the source thereof being connected to the vertical signal line VSL through the selection transistor SEL.

The selection transistor SEL is connected between the source of the amplifier transistor AMP and the vertical signal line VSL, and a control signal is supplied as a selection signal to the gate electrode of the selection transistor SEL. When the control signal is on, the selection transistor SEL enters a connected state, and the sensor pixel 121 connected to the selection transistor SEL enters a selected state accordingly. When the sensor pixel 121 is in the selected state, the pixel signal output from the amplifier transistor AMP is read out to the column signal processing circuit (the column signal processing unit 114) via the vertical signal line VSL.

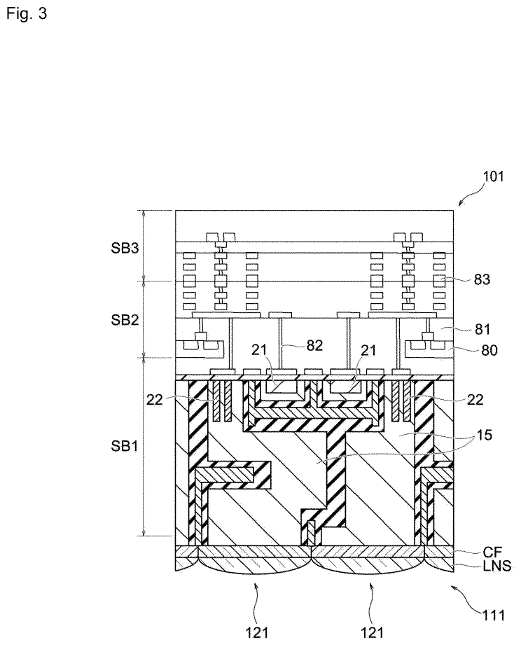

FIG. 3 is a cross-sectional view illustrating a schematic configuration of a part (two adjacent sensor pixels 121) of an example of the imaging device 101.

The imaging device 101 illustrated in FIG. 3 includes, as semiconductor substrates, a first semiconductor substrate SB1, a second semiconductor substrate SB2, and a third semiconductor substrate SB3 that are laminated one on another. The sensor pixels 121 are formed in the first semiconductor substrate SB1. A wiring layer 80 and an insulating layer 81 are formed in the second semiconductor substrate SB2.

A plurality of pixel drive lines 122 and a plurality of vertical signal lines 123 are formed in the wiring layer 80. The surroundings of the wiring layer 80 is covered by the insulating layer 81. Electrical connection is established between the first semiconductor substrate SB1 and the second semiconductor substrate SB2 by a through wire 82. Electrical connection is established between the second semiconductor substrate SB2 and the third semiconductor substrate BP3, for example, by a Cu—Cu bonding 83.

The specific configurations of the first semiconductor substrate SB1 to the third semiconductor substrate B3 are not limited. For example, the circuit configuration illustrated in FIG. 2 can be implemented in the first semiconductor substrate SB1 and the second semiconductor substrate SB2. As an example, the photoelectric conversion portion 15, the charge holding portion 21, the transfer transistor TRZ, the transfer transistor TRY, the transfer transistor TRX, and the transfer transistor TRG, which are illustrated in FIG. 2 can be formed in the first semiconductor substrate SB1. In this case, the discharge transistor OFG, the floating diffusion FD, the reset transistor RST, the amplifier transistor AMP, and the selection transistor SEL, which are illustrated in FIG. 2 can be formed in the second semiconductor substrate SB2.

For example, a logic circuit, a wiring layer, and an insulating layer can be formed in the third semiconductor substrate BP3. The logic circuit includes, for example, the vertical drive unit 112, the ramp wave module 113, the column signal processing unit 114, the clock module 115, the data storage unit 116, the horizontal drive unit 117, the system control unit 118, the signal processing unit 119, and the like, which are illustrated in FIG. 1. The surroundings of the logic circuit and the wiring layer are covered by the insulating layer.

These signal processing circuits such as a digital signal processor (DSP) (see peripheral circuits such as the signal processing unit 119 in FIG. 1) may have any form in the semiconductor substrate. For example, the signal processing circuits may be formed in a semiconductor layer of the second semiconductor substrate SB2 (typically in a peripheral region outside the effective pixel region), or may be formed in a third semiconductor substrate SB3 laminated on the second semiconductor substrate SB2.

The semiconductor substrates are not limited to having the configuration illustrated in FIG. 3, and may have any configuration. For example, the number of semiconductor substrates to be laminated is not limited, and only two semiconductor substrates (e.g., the first semiconductor substrate SB1 and the second semiconductor substrate SB2) may be provided as the semiconductor substrates of the imaging device 101.

Next, a specific example of the configuration of a solid-state imaging element (mainly the plurality of sensor pixels 121 of the pixel array unit 111) will be described.

In the following description, the X direction, Y direction, and Z direction are orthogonal to each other. The row direction and the column direction in which the plurality of sensor pixels 121 are arranged in the pixel array unit 111 described above correspond to the X direction and the Y direction, respectively.

### First Embodiment

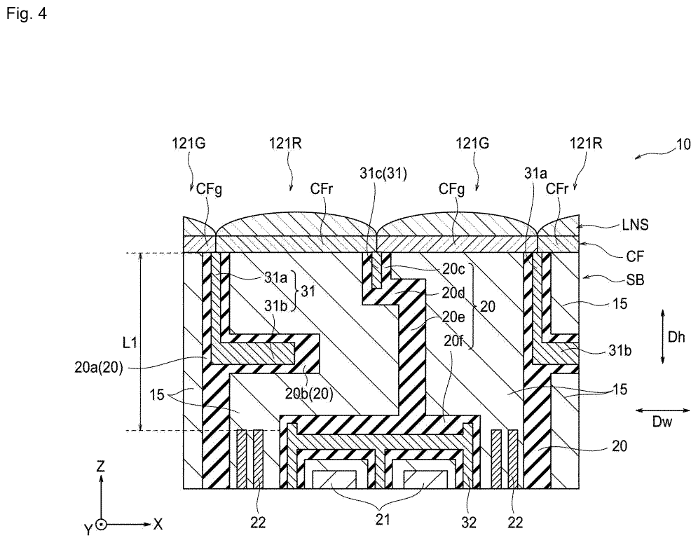

FIG. 4 is an enlarged cross-sectional view schematically illustrating an example of the solid-state imaging element 10 (particularly effective pixel region) according to a first embodiment.

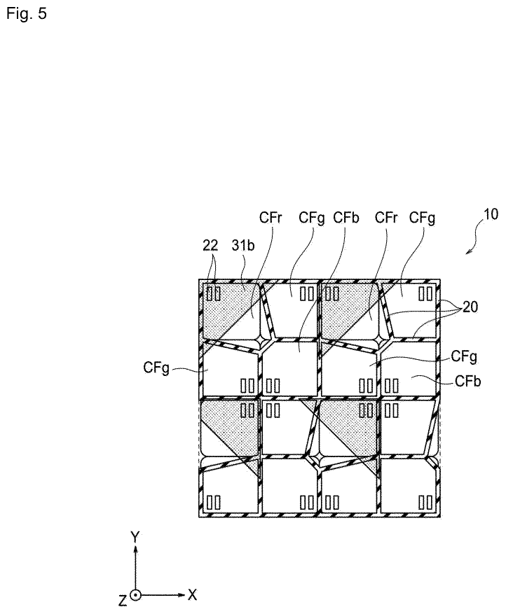

FIG. 5 is an enlarged top view of the solid-state imaging element 10 illustrated in FIG. 4, schematically illustrating an arrangement example of a color filter CF (R filter portions CFr, G filter portions CFg, and B filter portions CFb), a pixel separation portion 20, vertical electrodes 22, and second light-shielding portions 31b.

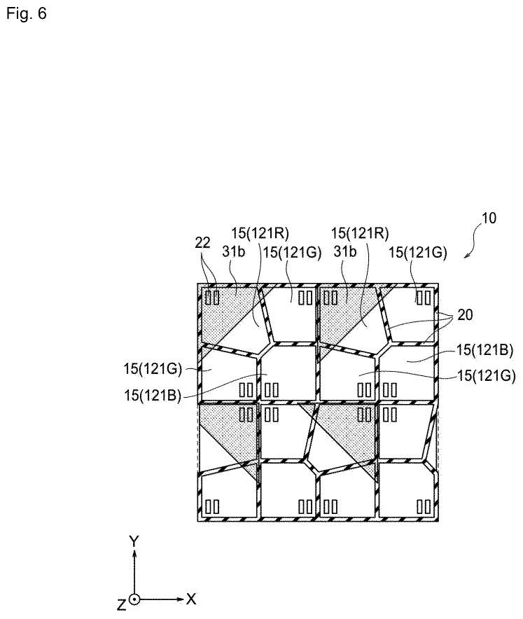

FIG. 6 is an enlarged top view of the solid-state imaging element 10 illustrated in FIG. 4, schematically illustrating an arrangement example of a photoelectric conversion portion 15, the pixel separation portion 20, the vertical electrodes 22, and the second light-shielding portions 31b, with the color filter CF omitted.

For a clear understanding of the arrangement relationship between the members, FIGS. 5 and 6 illustrate the members ignoring their positional relationship in the Z direction.

The solid-state imaging element 10 illustrated in FIGS. 4 to 6 includes a light-receiving lens LNS, a color filter CF, and a semiconductor substrate SB, which are stacked in a depth direction Dh (Z direction). In the examples illustrated in FIGS. 4 to 6, the back surface (the top surface in FIG. 4) of the semiconductor substrate SB forms a light-receiving surface on which light from a subject is incident, and is covered by the color filter CF.

The light-receiving lens LNS is configured as an on-chip microlens that is an assembly of a plurality of convex lenses. Light from the subject (imaging light) is collected by each convex lens and guided to the corresponding sensor pixel 121.

The color filter CF includes a plurality of color filter portions assigned to the plurality of sensor pixels 121, respectively. These color filter portions are classified into a plurality of types having different transmission wavelength ranges.

The color filter CF of the present embodiment includes R filter portions CFr, G filter portions CFg, and B filter portions CFb. The R filter portion CFr selectively transmits light in the red wavelength range, the G filter portion CFg selectively transmits light in the green wavelength range, and the B filter portion CFb selectively transmits light in the blue wavelength range. Therefore, the R filter portion CFr corresponds to a first-type color filter portion that transmits light in a wavelength range on the longest wavelength side. The G filter portion CFg corresponds to a second-type color filter portion that transmits light in a wavelength range on the shorter wavelength side than the light transmission wavelength range of the R filter portion CFr. The B filter portion CFb corresponds to a third-type color filter portion that transmits light in a wavelength range on the shorter wavelength side than the light transmission wavelength range of the G filter portion CFg.

The color filter CF of the present embodiment has a so-called Bayer array. In the Bayer array, a basic array of “2 pixels (X direction)×2 pixels (Y direction)” is repeatedly arranged in each of the X direction and the Y direction. The basic array includes two G filter portions CFg arranged on one diagonal, and one R filter portion CFr and one B filter portion CFb arranged on the other diagonal. Therefore, a row in which R pixels 121R to which the R filter portion CFr is assigned and G pixels 121G to which the G filter portion CFg is assigned are arranged alternately, and a row in which G pixels 121G and B pixels 121B to which the B filter portion CFb is assigned are arranged alternately are arranged in the column direction.

The specific arrangement of the color filter CF is not limited to the Bayer array, and the color filter CF may have the Quad-Bayer array described below or any other array. The type and number of types of color filter portions included in the color filter CF are not limited either. The color filter CF may include color filter portions of colors other than RGB, or may include two or less types, or four or more types of color filter portions.

The semiconductor substrate SB includes a plurality of sensor pixels 121 (i.e., an R pixel 121R, a G pixel 121G, and a B pixel 121B). Each sensor pixel 121 includes the photoelectric conversion portion 15, the charge holding portion (MEM) 21, and the vertical electrodes (gate electrodes) 22.

The term “sensor pixel 121” can be used to refer to a set of members formed in the semiconductor substrate SB, and can also be used to refer to a set including a color filter CF and/or a light-receiving lens LNS in addition to the members formed in the semiconductor substrate SB.

The photoelectric conversion portion 15 is partitioned so as to be electrically isolated by the pixel separation portion 20, and performs photoelectric conversion of the light incident from the color filter CF to generate a charge (electrons). The charge generated in the photoelectric conversion portion 15 moves within the photoelectric conversion portion 15 toward the vertical electrode 22 and are collected by the vertical electrode 22.

The specific composition and shape of the photoelectric conversion portion 15 are not limited. For example, the photoelectric conversion portion 15 may include an N-type semiconductor region and a P-type semiconductor region, or may include a plurality of N-type semiconductor regions and/or a plurality of P-type semiconductor regions with different impurity concentrations.

At least a part of the vertical electrode 22 is embedded in the photoelectric conversion portion 15 and is electrically connected to the photoelectric conversion portion 15. The charge generated in the photoelectric conversion portion 15 is sent toward the charge holding portion 21 (MEM) via the vertical electrode 22. The vertical electrode 22 illustrated in FIG. 4 are provided as a part of the charge transfer portion (the readout circuit) including, for example, transistors, and cooperates with other portions (not illustrated) of the charge transfer portion to transfer the charge from the photoelectric conversion portion 15 to the charge holding portion 21. At least a part of the other portions of the charge transfer portion are provided, for example, on the front surface (the lower surface in FIG. 4) of the semiconductor substrate SB.

The charge holding portion 21 holds the charge sent from the photoelectric conversion portion 15 via the vertical electrode 22. The charge holding portion 21 is electrically isolated from the photoelectric conversion portion 15 by the pixel separation portion 20.

The charge holding portion 21 is a region that temporarily holds the charge generated by the photoelectric conversion portion 15 in order to implement a global shutter function. For example, by adjusting the potential of the charge holding portion 21 with a transfer transistor (not illustrated) provided between the vertical electrode 22 and the charge holding portion 21, the transfer of the charge from the vertical electrode 22 to the charge holding portion 21 and the sending of the charge from the charge holding portion 21 can be controlled. The charge sent from the charge holding portion 21 is subjected to various types of processing as required (see the ramp wave module 113 and the column signal processing unit 114 illustrated in FIG. 1), and is then sent as a pixel signal to the signal processing unit 119 (see FIG. 1).

The solid-state imaging element 10 of the present embodiment further includes a first light-shielding member 31 and a second light-shielding member 32, which are provided in the pixel separation portion 20. The first light-shielding member 31 and the second light-shielding member 32, which are illustrated in FIG. 4 are embedded in the pixel separation portion 20 and isolated from the photoelectric conversion portion 15 through the pixel separation portion 20.

The light-shielding members as used herein (the first light-shielding member 31, the second light-shielding member 32, and a third light-shielding member 33 described later) have excellent light absorption or reflection characteristics, which suppress light transmission, but they are not necessary to completely block all light (e.g., visible light). The light-shielding members (the first light-shielding member 31, the second light-shielding member 32, and the third light-shielding member 33 described later) may have the same composition or may have different compositions. The light-shielding members may be made of, for example, a material containing at least one of a single metal, a metal alloy, a metal nitride, and a metal silicide with a light shielding property.

The first light-shielding member 31 is disposed between adjacent pixels (between the R pixel 121R and the G pixel 121G in FIG. 4) on the side closer to the color filter CF than the vertical electrode 22 is. This makes it possible to prevent leakage of light from and to adjacent pixels so as not to mix colors of pixels.

On the other hand, the second light-shielding member 32 is disposed between the photoelectric conversion portion 15 and the charge holding portion 21 so as to cover the charge holding portion 21. This makes it possible to prevent light from entering the charge holding portion 21 and thus to prevent noise caused by the light from occurring in the charge held in the charge holding portion 21.

The first light-shielding member 31 has different structures depending on the relative positions of adjacent types of pixels (particularly adjacent types of pixels including the R pixel 121R).

Specifically, the first light-shielding member 31 includes a first light-shielding portion 31a that extends in the depth direction Dh from the light-receiving surface of the semiconductor substrate SB, and a second light-shielding portion 31b that is connected to the first light-shielding portion 31a and that extends in a width direction Dw perpendicular to the depth direction Dh. The second light-shielding portion 31b is disposed at a position that overlaps with the vertical electrode 22 (the charge transfer portion) of the R pixel 121R (a first-type pixel) when viewed from above in the depth direction Dh (the Z direction).

The second light-shielding portion 31b thus disposed can prevent the light that has entered the photoelectric conversion portion 15 through the color filter CF (particularly the R filter portion CFr) from entering the vertical electrode 22, and thus effectively reduce PLS noise. Since the light reflected by the second light-shielding portion 31b may generate a charge when passing through the photoelectric conversion portion 15, the second light-shielding portion 31b can improve the photoelectric conversion efficiency.

At least a part of the portion of the pixel separation portion 20 that faces the second light-shielding portion 31b in the width direction Dw is disposed at a position that does not overlap with the R filter portion CFr but overlaps with the G filter portion CFg when viewed from above in the depth direction Dh.

This makes it possible to ensure a large cross-sectional area in the region of the photoelectric conversion portion 15 adjacent to the second light-shielding portion 31b in the width direction Dw. Therefore, even with a structure that the second light-shielding portion 31b and the pixel separation portion 20 protrude in the width direction Dw in the photoelectric conversion portion 15 of the R pixel 121R, the cross-sectional area of the photoelectric conversion portion 15 in the width direction Dw is prevented from being locally reduced so that the smooth flow of electrons in the photoelectric conversion portion 15 is promoted.

With such a configuration, not only the region of the photoelectric conversion portion 15 that overlaps with the R filter portion CFr in the depth direction Dh, but also the partial region of the photoelectric conversion portion 15 that overlaps with the G filter portion CFg in the depth direction Dh are used as the photoelectric conversion portion 15 of the R pixel 121R. As a result, the volume of the photoelectric conversion portion 15 of the G pixel 121G adjacent to the R pixel 121R becomes smaller than the volume of the photoelectric conversion portion 15 of the R pixel 121R. However, since the sensitivity of the photoelectric conversion portion 15 to green light is generally higher than the sensitivity to red light, a reduction in the volume of the photoelectric conversion portion 15 of the G pixel 121G has little substantial adverse effect on captured images.

Results verification of the time (saturation time) from when the photoelectric conversion portion 15 is irradiated with light until the charge held by the charge holding portion 21 reaches a saturated state and the charge accumulation state showed that the saturation time for green light is shorter than the saturation time for red light and blue light. Therefore, the charge holding portion 21 of the G pixel 121G is likely to reach the charge accumulation saturation state before the charge holding portion 21 of the R pixel 121R and the charge holding portion 21 of the B pixel 121B do so.

Therefore, even if the volume of the photoelectric conversion portion 15 of the G pixel 121G is smaller than the volume of the photoelectric conversion portion 15 of the R pixel 121R as in the present embodiment, the charge holding portion 21 of the G pixel 121G can accumulate a sufficient amount of charge in a limited amount of time.

In the examples illustrated in FIGS. 4 to 6, the vertical electrode 22 of the R pixel 121R is located on the left side in the R pixel 121R in the X direction in FIGS. 4 to 6. On the other hand, in the examples illustrated in FIGS. 4 to 6, the vertical electrode 22 of the G pixel 121G adjacent to the R pixel 121R in the X direction is located on the right side in the G pixel 121G in the X direction in FIGS. 4 to 6.

Accordingly, the second light-shielding portion 31b that covers the vertical electrode 22 of the R pixel 121R is provided in the pixel separation portion 20 located on one side in the X direction (the left side in FIG. 4) with respect to the photoelectric conversion portion 15 of the R pixel 121R. On the other hand, the second light-shielding portion 31b is not provided in the pixel separation portion 20 located on the other side in the X direction (the right side in FIG. 4) with respect to the photoelectric conversion portion 15 of the R pixel 121R, and instead, a third light-shielding portion 31c that extends in the depth direction Dh is provided as the first light-shielding member 31.

Accordingly, the pixel separation portion 20 on one side in the X direction (the left side in FIG. 4) with respect to the photoelectric conversion portion 15 of the R pixel 121R has a vertical portion 20a that extends linearly in the depth direction Dh, and a horizontal portion 20b that protrudes linearly from the middle of the vertical portion 20a in the width direction Dw. The first light-shielding portion 31a is located in the vertical portion 20a, and the second light-shielding portion 31b is located in the horizontal portion 20b.

On the other hand, the pixel separation portion 20 on the other side in the X direction (the right side in FIG. 4) with respect to the photoelectric conversion portion 15 of the R pixel 121R has a first vertical portion 20c, a horizontal portion 20d, a second vertical portion 20e, and a covering portion 20f. The first vertical portion 20c extends linearly from the back surface (the light-receiving surface) of the semiconductor substrate SB in the depth direction Dh. The horizontal portion 20d extends linearly from an end of the first vertical portion 20c in the width direction Dw. The second vertical portion 20e extends linearly from an end of the horizontal portion 20d in the depth direction Dh. The covering portion 20f extends from an end of the second vertical portion 20e in the depth direction Dh, and covers the charge holding portion 21 of each of the adjacent R pixel 121R and G pixel 121G.

The first vertical portion 20c and the third light-shielding portion 31c embedded in the first vertical portion 20c are located closer to the color filter CF than the horizontal portion 20b and the second light-shielding portion 31b are in the depth direction Dh. On the other hand, the covering portion 20f and the second light-shielding member 32 embedded in the covering portion 20f are located farther from the color filter CF than the horizontal portion 20b and the second light-shielding portion 31b are in the depth direction Dh.

The first light-shielding member 31 having any shape (e.g., as with the third light-shielding portion 31c in FIG. 1, a shape extending in the depth direction Dh) is provided in the pixel separation portion 20 that separates the photoelectric conversion portion 15 of the B pixel 121B and the photoelectric conversion portion 15 of the G pixel 121G, which are adjacent to each other in the X direction.

In this way, the vertical electrode 22 of the R pixel 121R is covered by the second light-shielding portion 31b and thus shielded from light. On the other hand, the vertical electrodes 22 of the G pixel 121G and the B pixel 121B are not covered by the second light-shielding portion 31b and thus not shielded from light. However, a distance L1 in the depth direction Dh between the light-receiving surface of the photoelectric conversion portion 15 and the vertical electrode 22 is designed to be sufficiently long, so that the green light and blue light that has entered the photoelectric conversion portion 15 are attenuated by the photoelectric conversion portion 15 and do not at all or hardly reach the vertical electrodes 22 substantially.

Generally, in the photoelectric conversion portion 15 (e.g., single-crystal silicon), light with a shorter wavelength is more easily absorbed and attenuated by the photoelectric conversion portion 15, and light with a longer wavelength is less likely to be attenuated in the photoelectric conversion portion 15 and thus reach a deep point of the photoelectric conversion portion 15.

The inventor(s) examined, with an actual device, reachable depths of red light that passed through the R filter portion CFr, green light that passed through the G filter portion CFg, and blue light that passed through the B filter portion CFb in a photoelectric conversion portion 15 made of single-crystal silicon. As a result, the light intensity of the blue light was attenuated to almost 0% at a depth of 2 μm from the light-receiving surface of the single-crystal silicon. The light intensity of the green light was attenuated to almost 0% at a depth of 5 μm from the light-receiving surface of the single-crystal silicon. On the other hand, for the red light, a light intensity of nearly 40% at a depth of 5 μm from the light-receiving surface of the single-crystal silicon was shown.

As is clear from these experimental results, for a sufficiently long distance L1 in the depth direction Dh between the light-receiving surface of the photoelectric conversion portion 15 and the vertical electrode 22, the blue light and the green light do not reach the vertical electrode 22 even without light shielding by the second light-shielding portion 31b. Therefore, it is possible to effectively reduce PLS noise. Accordingly, the distance L1 in the depth direction Dh from the light-receiving surface of the photoelectric conversion portion 15 to the vertical electrode 22 is designed such that the light intensity of blue light and green light is attenuated to 10% or less, more preferably 5% or less, and even preferably 1% or less, for example. As an example, for a distance L1 of 2.0 μm or more, or more preferably 5.0 μm or more in the depth direction Dh between the light-receiving surface of the photoelectric conversion portion 15 and the vertical electrode 22, it is possible to effectively reduce PLS noise.

The pixel separation portion 20 and the first light-shielding member 31, which are located on both sides in the Y direction with respect to the photoelectric conversion portion 15 of the R pixel 121R also have the same configuration as “the pixel separation portion 20 and the first light-shielding member 31, which are located on both sides in the X direction with respect to the photoelectric conversion portion 15 of the R pixel 121R”.

As illustrated in FIGS. 5 and 6, each of the second light-shielding portions 31b of this example having the above-described configuration has a triangular planar shape (particularly, a right-angled isosceles triangle with two sides extending along the X direction and the Y direction, respectively, and intersecting with each other). The vertical electrode 22 of each R pixel 121R is located in a region corresponding to a 90° corner portion of the planar shape (right-angled isosceles triangle) of the second light-shielding portion 31b (i.e., in the vicinity of the intersection of the sides forming the corner portion).

As illustrated in FIGS. 5 and 6, when viewed from above (Z direction), the pixel separation portion 20 that partitions each R pixel 121R partially overlaps with not only the R filter portion CFr but also two G filter portions CFg adjacent to each other in the X direction and the Y direction and one of diagonally adjacent B filter portions CFb. Thus, the pixel separation portion 20 and each sensor pixel 121 (R pixel 121R, G pixel 121G, and B pixel 121B) have an asymmetric planar structure with respect to both the X direction and the Y direction.

### Second Embodiment

In the present embodiment, the same or corresponding portions/members as those in the first embodiment described above are designated by the same reference numerals, and detailed description thereof will be omitted.

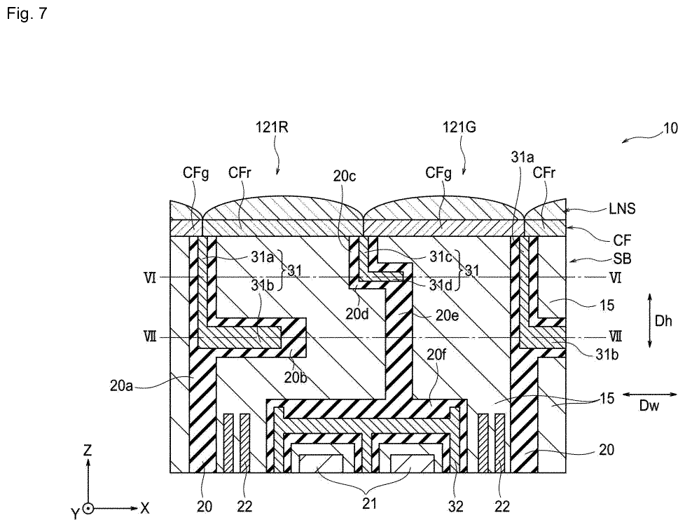

FIG. 7 is an enlarged cross-sectional view schematically illustrating an example of a solid-state imaging element 10 according to a second embodiment.

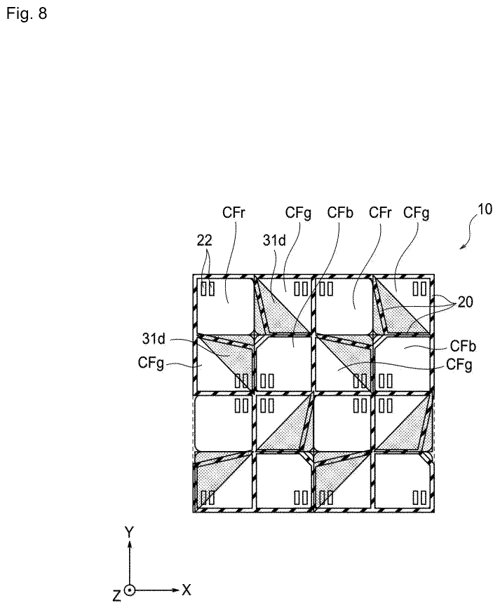

FIG. 8 is an enlarged top view of the solid-state imaging element 10 illustrated in FIG. 7, schematically illustrating an arrangement example of a color filter CF, a pixel separation portion 20, vertical electrodes 22, and fourth light-shielding portions 31d. The fourth light-shielding portions 31d in FIG. 8 are illustrated in a cross section taken along the cross-sectional line VI-VI in FIG. 7.

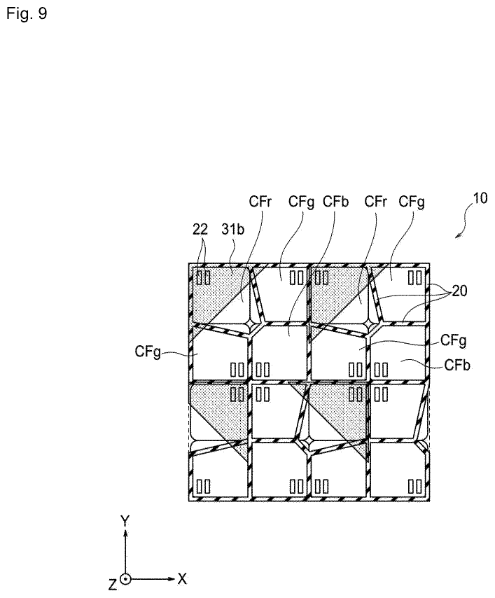

FIG. 9 is an enlarged top view of the solid-state imaging element 10 illustrated in FIG. 7, schematically illustrating an arrangement example of the color filter CF, the pixel separation portion 20, the vertical electrodes 22, and second light-shielding portions 31b. The second light-shielding portions 31b in FIG. 9 are illustrated in a cross section taken along a cross-sectional line VII-VII in FIG. 7.

For a clear understanding of the arrangement relationship between the members, FIGS. 8 and 9 illustrate the members ignoring their positional relationship in the Z direction.

Also in the present embodiment, the first light-shielding portion 31a and the second light-shielding portion 31b are provided as the first light-shielding member 31 in the pixel separation portion 20 located on one side in the X direction (the left side in FIG. 7) with respect to the photoelectric conversion portion 15 of the R pixel 121R. On the other hand, in addition to the third light-shielding portion 31c described above, the fourth light-shielding portion 31d is provided as the first light-shielding member 31 in the pixel separation portion 20 located on the other side in the X direction (the right side in FIG. 7) with respect to the photoelectric conversion portion 15 of the R pixel 121R.

The fourth light-shielding portion 31d is connected to an end of the third light-shielding portion 31c and extends in the width direction Dw. The fourth light-shielding portion 31d is embedded in the horizontal portion 20d of the pixel separation portion 20, and is electrically isolated from the photoelectric conversion portion 15 of the R pixel 121R and the photoelectric conversion portion 15 of the G pixel 121G.

The fourth light-shielding portion 31d is disposed at a position that partially overlaps with both the photoelectric conversion portion 15 of the R pixel 121R and the photoelectric conversion portion 15 of the G pixel 121G when viewed from above in the depth direction Dh. The fourth light-shielding portion 31d is also disposed at a different position in the depth direction Dh from the horizontal portion 20b and the second light-shielding portion 31b and between the photoelectric conversion portion 15 of the R pixel 121R and the photoelectric conversion portion 15 of the G pixel 121G. Specifically, as illustrated in FIG. 7, the fourth light-shielding portion 31d is located closer to the color filter CF than the horizontal portion 20b and the second light-shielding portion 31b are in the depth direction Dh.

As illustrated in FIG. 8, each of the fourth light-shielding portions 31d of this example has a triangular planar shape (particularly, a right-angled isosceles triangle with sides extending along the X direction and the Y direction, respectively), and is covered by the G filter portion CFg.

The other configurations of the solid-state imaging element 10 of the present embodiment are the same as those in the first embodiment described above.

According to the present embodiment, the fourth light-shielding portion 31d can prevent leakage of light from and to adjacent sensor pixels 121 (particularly leakage of light from the G pixel 121G to the R pixel 121R).

This makes it possible not to mix colors of pixels, and possible to effectively prevent PLS noise (e.g., PLS noise caused by light leaking from the G pixel 121G to the R pixel 121R).

### Third Embodiment

In the present embodiment, the same or corresponding portions/members as those in the second embodiment described above are designated by the same reference numerals, and detailed description thereof will be omitted.

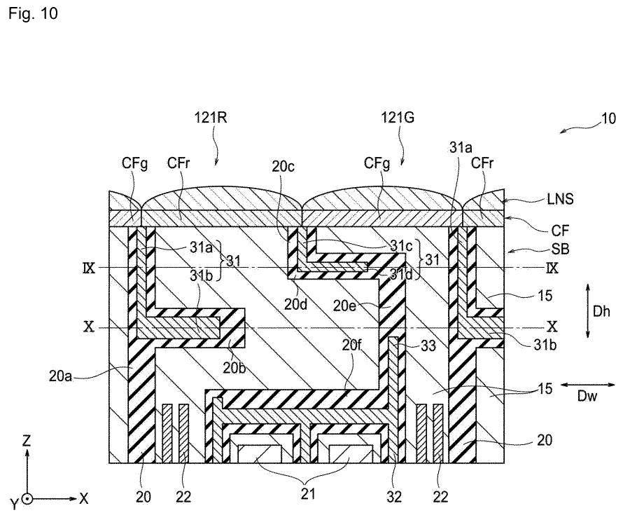

FIG. 10 is an enlarged cross-sectional view schematically illustrating an example of a solid-state imaging element 10 according to a third embodiment.

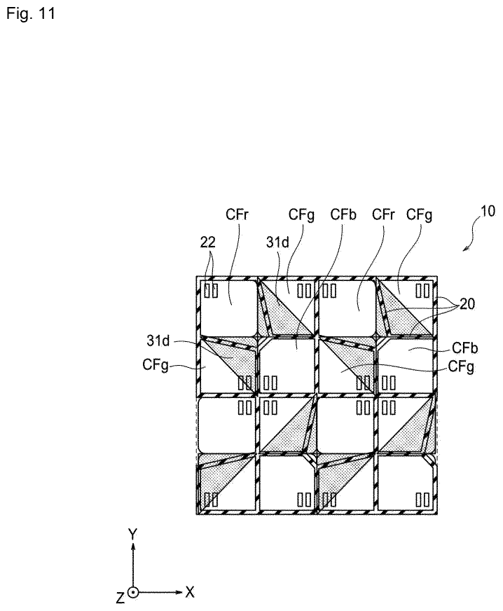

FIG. 11 is an enlarged top view of the solid-state imaging element 10 illustrated in FIG. 10, schematically illustrating an arrangement example of a color filter CF, a pixel separation portion 20, vertical electrodes 22, and fourth light-shielding portions 31d. The fourth light shielding portions 31d in FIG. 11 are illustrated in a cross section taken along a cross-sectional line IX-IX in FIG. 10.

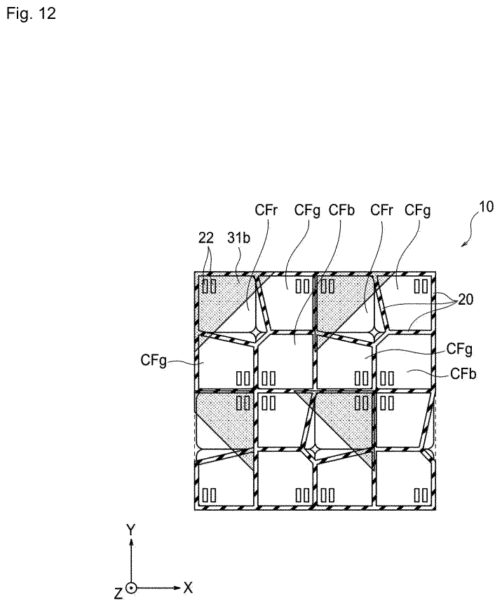

FIG. 12 is an enlarged top view of the solid-state imaging element 10 illustrated in FIG. 10, schematically illustrating an arrangement example of the color filter CF, the pixel separation portion 20, the vertical electrodes 22, and second light-shielding portions 31b. The second light-shielding portions 31b in FIG. 12 are illustrated in a cross section taken along a cross-sectional line X-X in FIG. 10.

For a clear understanding of the arrangement relationship between the members, FIGS. 11 and 12 illustrate the members ignoring their positional relationship in the Z direction.

Also in the present embodiment, the first light-shielding portion 31a and the second light-shielding portion 31b are provided as the first light-shielding member 31 in the pixel separation portion 20 located on one side in the X direction (the left side in FIG. 10) with respect to the photoelectric conversion portion 15 of the R pixel 121R. The third light-shielding portion 31c and the fourth light-shielding portion 31d are provided as the first light-shielding member 31 in the pixel separation portion 20 located on the other side in the X direction (the right side in FIG. 10) with respect to the photoelectric conversion portion 15 of the R pixel 121R.

In the present embodiment, a third light-shielding member 33 is further provided in addition to the first light-shielding member 31 (the first light-shielding portion 31a, the second light-shielding portion 31b, the third light-shielding portion 31c, and the fourth light-shielding portion 31d) and the second light-shielding member 32, which are described above.

The third light-shielding member 33 is disposed closer to the color filter CF than the vertical electrode 22 (charge transfer portion) is, and extends in the depth direction Dh between the photoelectric conversion portion 15 of the adjacent R pixel 121R and the photoelectric conversion portion 15 of the G pixel 121G, which are adjacent to each other.

The third light-shielding member 33 of this example is embedded in a second vertical portion 20e and a covering portion 20f of the pixel separation portion 20, which are located on the other side in the X direction (on the right side in FIG. 10) with respect to the photoelectric conversion portion 15 of the R pixel 121R, and is connected to the second light-shielding member 32. In other words, the third light-shielding member 33 is provided integrally with the second light-shielding member 32.

At least a part of the third light-shielding member 33 is disposed at a different position in the depth direction Dh from the horizontal portion 20b and the second light-shielding portion 31b and between the photoelectric conversion portion 15 of the R pixel 121R and the photoelectric conversion portion 15 of the G pixel 121G. Specifically, as illustrated in FIG. 10, the third light-shielding member 33 is located farther from the color filter CF than the second light-shielding portion 31b is in the depth direction Dh.

The other configurations of the solid-state imaging element 10 of the present embodiment are the same as those in the second embodiment described above.

According to the present embodiment, the third light-shielding member 33 can prevent leakage of light from and to adjacent sensor pixels 121 (particularly leakage of light from the G pixel 121G to the R pixel 121R).

This makes it possible not to mix colors of pixels, and possible to effectively prevent PLS noise (e.g., PLS noise caused by light leaking from the G pixel 121G to the R pixel 121R).

### Fourth Embodiment

In the present embodiment, the same or corresponding portions/members as those in the first embodiment described above are designated by the same reference numerals, and detailed description thereof will be omitted.

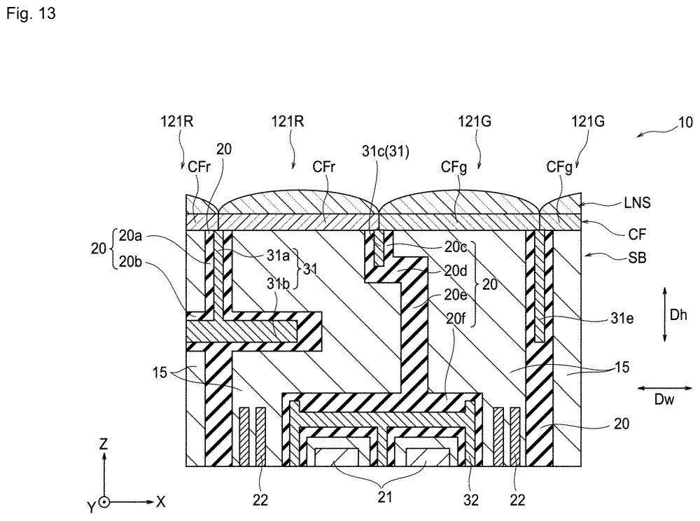

FIG. 13 is an enlarged cross-sectional view schematically illustrating an example of a solid-state imaging element 10 according to a fourth embodiment.

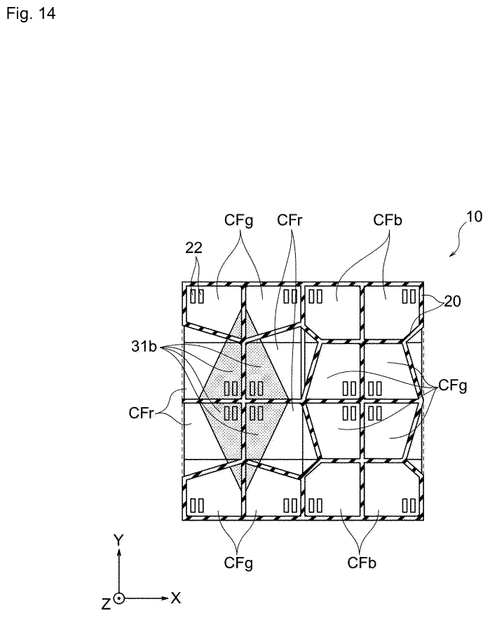

FIG. 14 is an enlarged top view of the solid-state imaging element 10 illustrated in FIG. 13, schematically illustrating an arrangement example of a color filter CF, a pixel separation portion 20, vertical electrodes 22, and second light-shielding portions 31b. For a clear understanding of the arrangement relationship between the members, FIG. 14 illustrates the members ignoring their positional relationship in the Z direction.

The color filter CF of the present embodiment has a so-called Quad-Bayer array. In the Quad-Bayer array, a basic array of “4 pixels (X direction)×4 pixels (Y direction)” is repeatedly arranged in each of the X direction and the Y direction. The basic array includes two sets of G filter portion groups each made up of “2 pixels (X direction)×2 pixels (Y direction)”, and the two sets of G filter portion groups are arranged on one diagonal line. The basic array includes one set of R filter portion group made up of “2 pixels (X direction)×2 pixels (Y direction)” and one set of B filter portion group made up of “2 pixels (X direction)×2 pixels (Y direction)”, which are adjacent to each other in the X direction and the Y direction of each G filter portion group and are arranged on the other diagonal.

Thus, two R pixels 121R are consecutively arranged in each of the X direction and the Y direction. Further, two consecutively arranged R pixels 121R and two consecutively arranged G pixels 121G are adjacent to each other in each of the X direction and the Y direction.

The first light-shielding portion 31a and the second light-shielding portion 31b of the present embodiment are provided in the pixel separation portion 20 (the vertical portion 20a and the horizontal portion 20b) that separates the two adjacent R pixels 121R. The third light-shielding portion 31c is provided in the pixel separation portion 20 (the first vertical portion 20c) that separates the adjacent R pixel 121R and G pixel 121G.

The second light-shielding portion 31b is provided in the horizontal portion 20b of the pixel separation portion 20 that separates the two adjacent R pixels 121R. The second light-shielding portion 31b illustrated in FIG. 13 extends from an end of the first light-shielding portion 31a toward each of the photoelectric conversion portions 15 of the two adjacent R pixels 121R in the width direction Dw (the left direction and the right direction in FIG. 13), and covers each of the vertical electrodes 22 of the two adjacent R pixels 121R.

In other words, the vertical electrodes 22 of the two adjacent R pixels 121R are disposed at positions that overlap with the second light-shielding portion 31b when viewed from above in the depth direction Dh in the vicinity of the pixel separation portion 20 that separates the two adjacent R pixels 121R. In this example, as illustrated in FIG. 14, the vertical electrode 22 of each of the four R pixels 121R arranged adjacent to each other in the X direction and the Y direction is covered by the second light-shielding portion 31b that is integrally provided.

The horizontal portion 20b of the pixel separation portion 20 protrudes linearly in the width direction Dw from the middle of the vertical portion 20a, and covers the second light shielding portion 31b. The first vertical portion 20c, the horizontal portion 20d, the second vertical portion 20e, and the covering portion 20f are provided as the pixel separation portion 20 that separates the adjacent R pixel 121R and G pixel 121G.

A fifth light-shielding portion 31e that extends in the depth direction Dh is provided in the pixel separation portion 20 that separates the photoelectric conversion portions 15 of the two adjacent G pixels 121G.

The other configurations of the solid-state imaging element 10 of the present embodiment are the same as those in the first embodiment described above.

Even for the color filter CF having the Quad-Bayer array as in the present embodiment, the second light-shielding portion 31b can prevent the light that has passed through the color filter CF (particularly the R filter portion CFr) from entering the vertical electrode 22, and thus effectively reduce PLS noise. Even with a structure in which the second light-shielding portion 31b and the pixel separation portion 20 (the horizontal portion 20b) protrude in the width direction Dw in the photoelectric conversion portion 15 of the R pixel 121R, the cross-sectional area of the photoelectric conversion portion 15 in the width direction Dw is prevented from being locally reduced so that the smooth flow of electrons in the photoelectric conversion portion 15 is promoted.

### Fifth Embodiment

In the present embodiment, the same or corresponding portions/members as those in the second and fourth embodiments described above are designated by the same reference numerals, and detailed description thereof will be omitted.

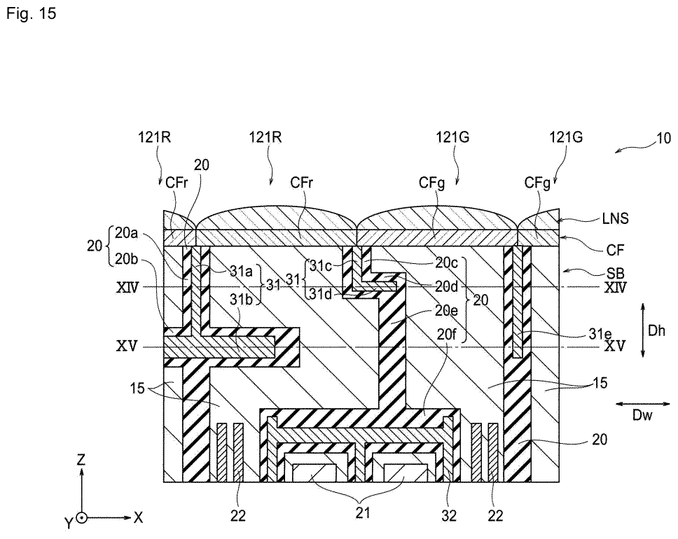

FIG. 15 is an enlarged cross-sectional view schematically illustrating an example of a solid-state imaging element 10 according to a fifth embodiment.

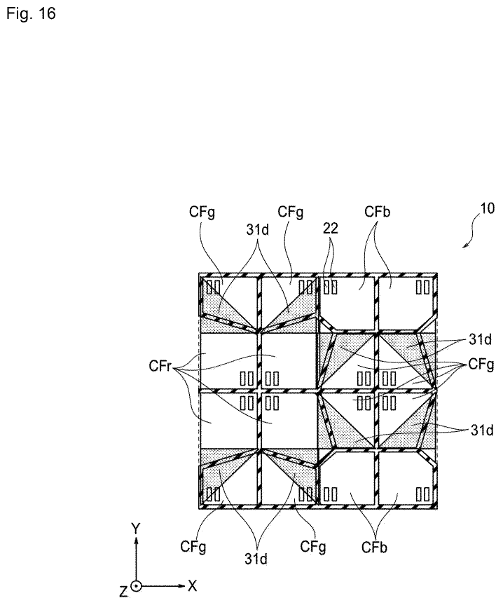

FIG. 16 is an enlarged top view of the solid-state imaging element 10 illustrated in FIG. 15, schematically illustrating an arrangement example of a color filter CF, a pixel separation portion 20, vertical electrodes 22, and fourth light-shielding portions 31d. The fourth light-shielding portions 31d in FIG. 16 are illustrated in a cross section taken along a cross-sectional line XIV-XIV in FIG. 15.

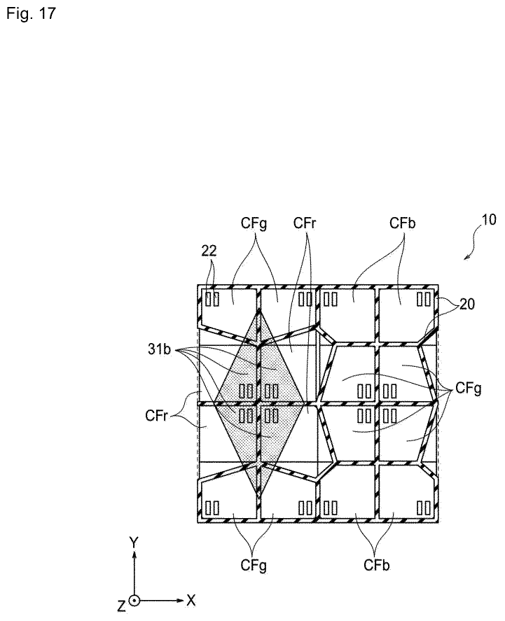

FIG. 17 is an enlarged top view of the solid-state imaging element 10 illustrated in FIG. 15, schematically illustrating an arrangement example of the color filter CF, the pixel separation portion 20, the vertical electrodes 22, and second light-shielding portions 31b. The second light-shielding portions 31b in FIG. 17 are illustrated in a cross section taken along a cross-sectional line XV-XV in FIG. 15.

For a clear understanding of the arrangement relationship between the members, FIGS. 16 and 17 illustrate the members ignoring their positional relationship in the Z direction.

The color filter CF of the present embodiment also has a Quad-Bayer array.

Similarly to the fourth embodiment described above, the second light-shielding portion 31b is provided in the pixel separation portion 20 that separates two adjacent R pixels 121R. The second light-shielding portion 31b illustrated in FIG. 15 extends in the width direction Dw from an end of the first light-shielding portion 31a toward the photoelectric conversion portions 15 of the two adjacent R pixels 121R, and covers the vertical electrodes 22 of the two adjacent R pixels 121R.

In other words, the vertical electrodes 22 of the two adjacent R pixels 121R are disposed at positions that overlap with the second light-shielding portion 31b when viewed from above in the depth direction Dh in the vicinity of the pixel separation portion 20 that separates the two adjacent R pixels 121R. In this example, as illustrated in FIG. 17, the vertical electrode 22 of each of the four R pixels 121R arranged adjacent to each other in the X direction and the Y direction is covered by the second light-shielding portion 31b that is integrally provided.

The other configurations of the solid-state imaging element 10 of the present embodiment are the same as those in the second and fourth embodiments described above.

Specifically, in addition to the first light-shielding portion 31a, the second light-shielding portion 31b, and the third light-shielding portion 31c, a fourth light-shielding portion 31d is provided as the first light-shielding member 31. The fourth light-shielding portion 31d is connected to an end of the third light-shielding portion 31c, extends in the width direction Dw, and is disposed at a position that partially overlaps with both the photoelectric conversion portion 15 of the R pixel 121R and the photoelectric conversion portion 15 of the G pixel 121G when viewed from above in the depth direction Dh.

Even for the color filter CF having the Quad-Bayer array as in the present embodiment, the fourth light-shielding portion 31d can prevent leakage of light from and to adjacent sensor pixels 121 (particularly leakage of light from the G pixel 121G to the R pixel 121R). This makes it possible not to mix colors of pixels, and possible to effectively prevent PLS noise (e.g., PLS noise caused by light leaking from the G pixel 121G to the R pixel 121R).

### Sixth Embodiment

In the present embodiment, the same or corresponding portions/members as those in the third and fifth embodiments described above are designated by the same reference numerals, and detailed description thereof will be omitted.

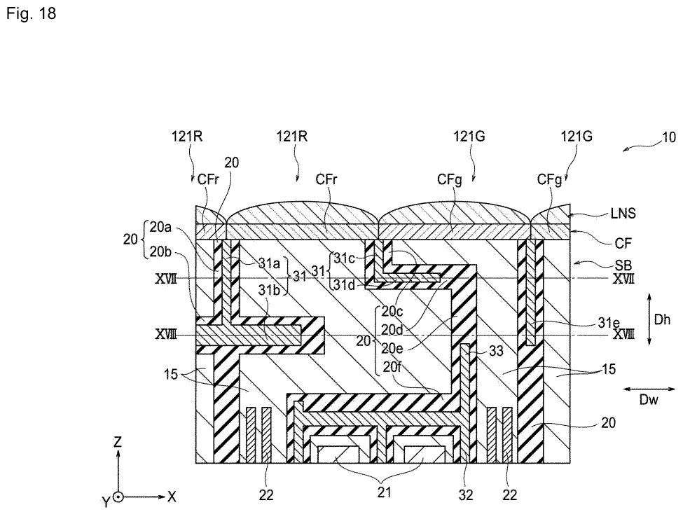

FIG. 18 is an enlarged cross-sectional view schematically illustrating an example of a solid-state imaging element 10 according to a sixth embodiment.

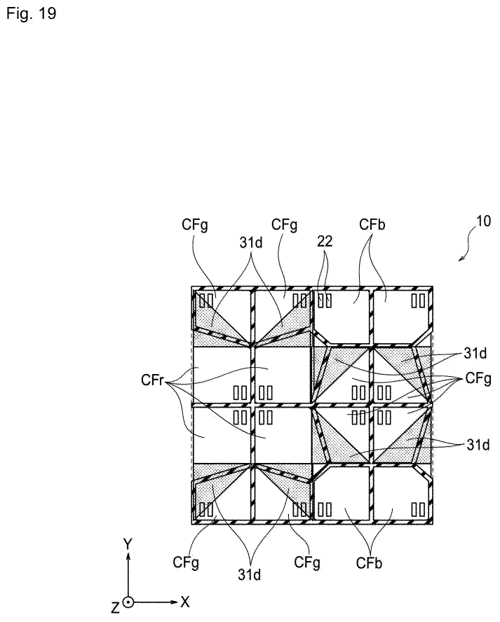

FIG. 19 is an enlarged top view of the solid-state imaging element 10 illustrated in FIG. 18, schematically illustrating an arrangement example of a color filter CF, a pixel separation portion 20, vertical electrodes 22, and fourth light-shielding portions 31d. The fourth light-shielding portions 31d in FIG. 19 are illustrated in a cross section taken along a cross-sectional line XVII-XVII in FIG. 18.

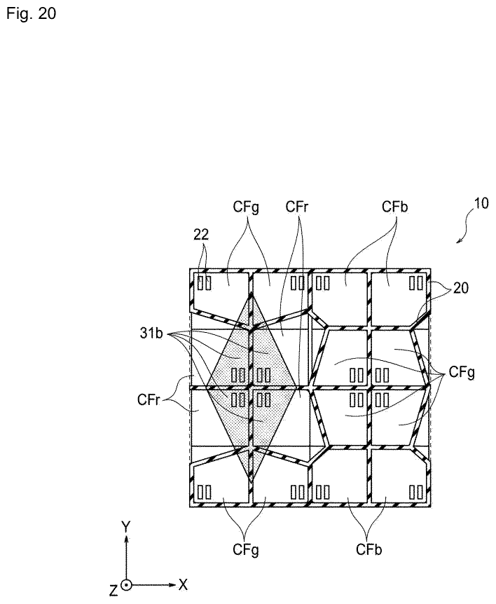

FIG. 20 is an enlarged top view of the solid-state imaging element 10 illustrated in FIG. 18, schematically illustrating an arrangement example of the color filter CF, the pixel separation portion 20, the vertical electrodes 22, and second light-shielding portions 31b. The second light-shielding portions 31b in FIG. 20 are illustrated in a cross section taken along a cross-sectional line XVIII-XVIII in FIG. 18.

For a clear understanding of the arrangement relationship between the members, FIGS. 19 and 20 illustrate the members ignoring their positional relationship in the Z direction.

The color filter CF of the present embodiment also has a Quad-Bayer array.

Similarly to the fifth embodiment described above, the second light-shielding portion 31b is provided in the pixel separation portion 20 that separates two adjacent R pixels 121R. The second light-shielding portion 31b illustrated in FIG. 18 extends in the width direction Dw from an end of the first light-shielding portion 31a toward the photoelectric conversion portions 15 of the two adjacent R pixels 121R, and covers the vertical electrodes 22 of the two adjacent R pixels 121R. The fourth light-shielding portion 31d is connected to an end of the third light-shielding portion 31c, extends in the width direction Dw, and is disposed at a position that partially overlaps with both the photoelectric conversion portion 15 of the R pixel 121R and the photoelectric conversion portion 15 of the G pixel 121G when viewed from above in the depth direction Dh.

The other configurations of the solid-state imaging element 10 of the present embodiment are the same as those in the third and fifth embodiments described above.

Specifically, the third light-shielding member 33 is provided closer to the color filter CF than the vertical electrode 22 is and farther from the color filter CF than the second light-shielding portion 31b is in the depth direction Dh, and between the photoelectric conversion portion 15 of the R pixel 121R and the photoelectric conversion portion 15 of the G pixel 121G, which are adjacent to each other.

Even for the color filter CF having the Quad-Bayer array as in the present embodiment, the third light-shielding member 33 can prevent leakage of light from and to adjacent sensor pixels 121 (particularly leakage of light from the G pixel 121G to the R pixel 121R). This makes it possible not to mix colors of pixels, and possible to effectively prevent PLS noise (e.g., PLS noise caused by light leaking from the G pixel 121G to the R pixel 121R).

### [Method of Manufacturing Solid-State Imaging Element]

Next, an example of a method of manufacturing the solid-state imaging element 10 will be described.

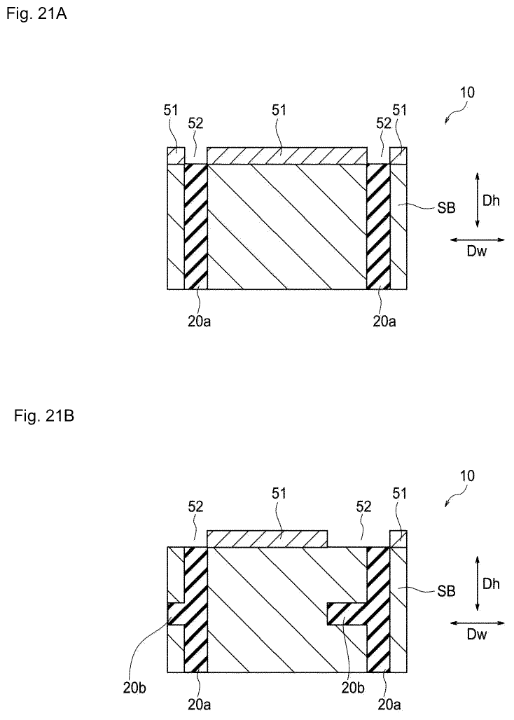

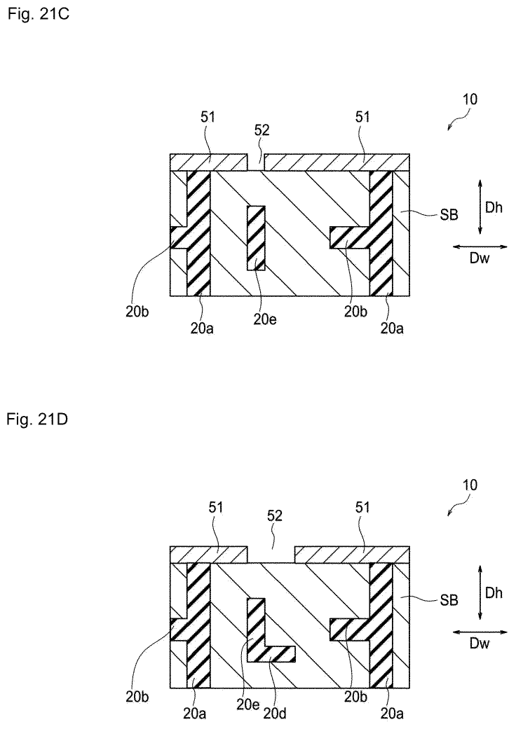

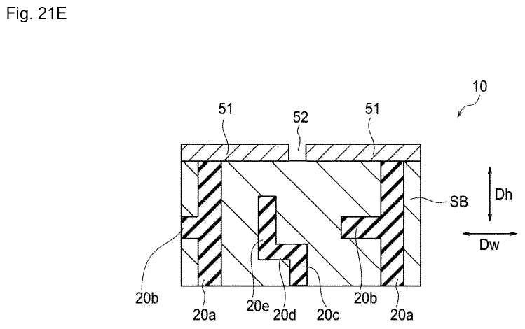

In the method of manufacturing the solid-state imaging element 10 illustrated below (FIGS. 21A to 23G), detailed descriptions of steps that can be performed based on known techniques will be omitted. For example, although not mentioned below, to perform etching (dry etching and wet etching), protective films with etching resistance are provided on portions to be protected as necessary, and the portions to be protected are protected by the protective films to prevent them from being etched.

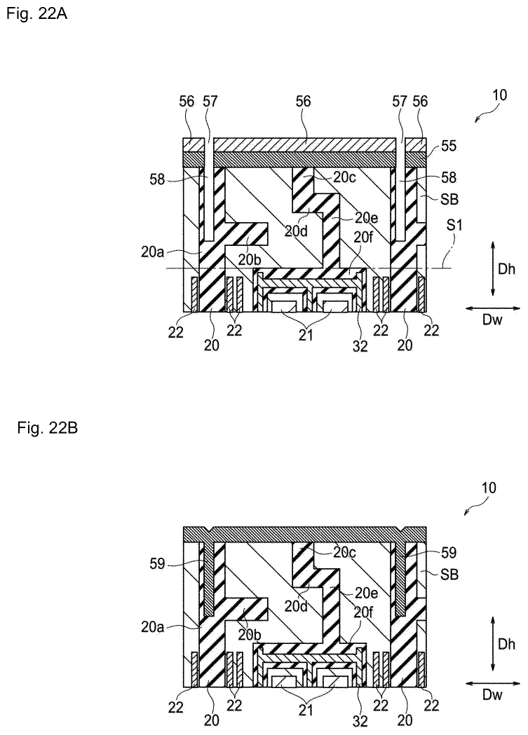

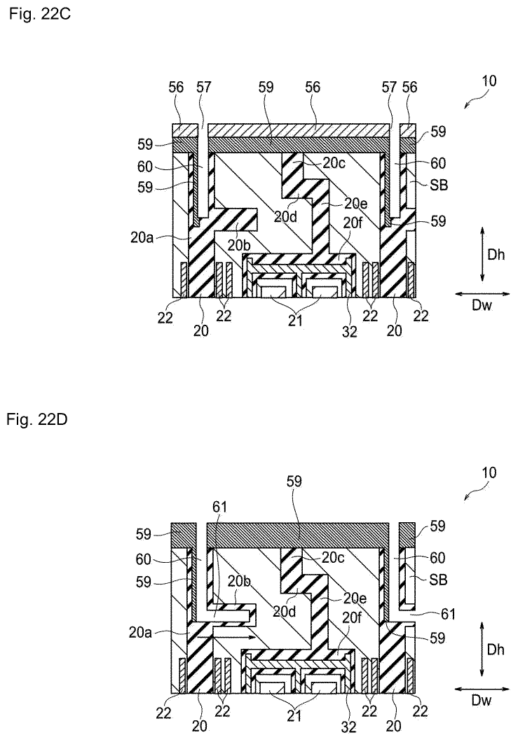

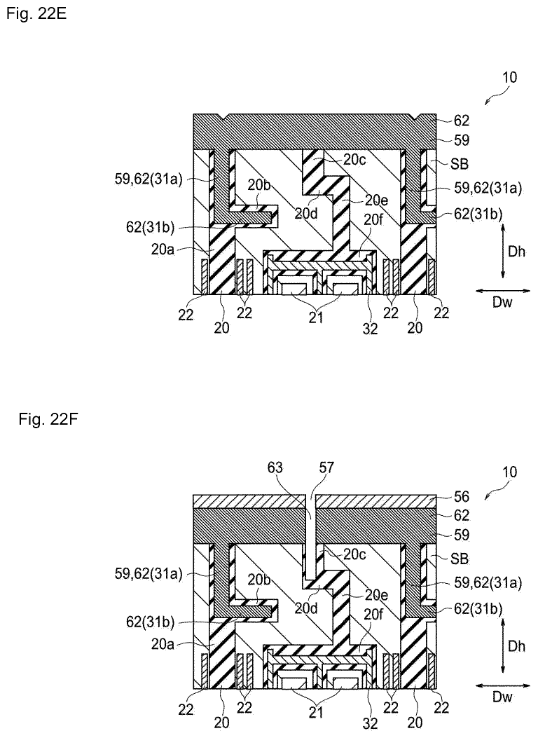

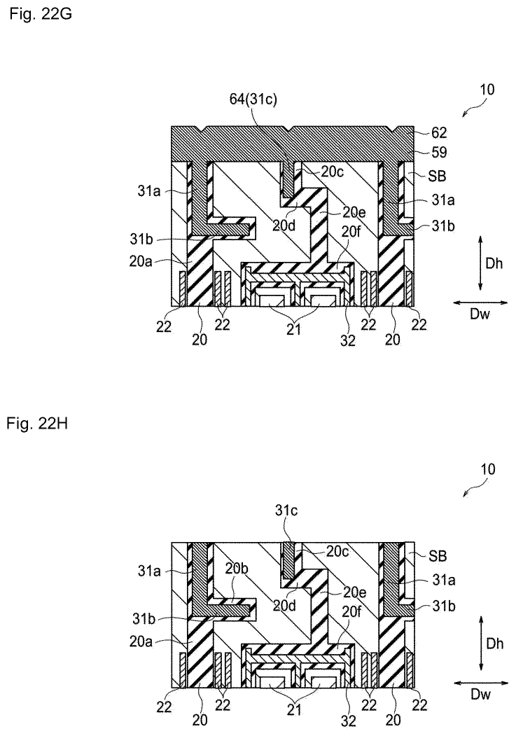

FIGS. 21A to 21E are cross-sectional views illustrating an example of the method of manufacturing the solid-state imaging element 10 (particularly the front-end-of-line (FEOL)). FIGS. 22A to 22H are cross-sectional views illustrating an example of the method of manufacturing the solid-state imaging element 10 (particularly the back-end-of-line (BEOL)).

First, a semiconductor substrate (e.g., a single crystal silicon substrate) SB is prepared. The semiconductor substrate SB used in this example has a crystal orientation with a plane index of (111). The plane index (111) refers to including crystal orientations such as (−111), (1-11), and (11-1) in which any direction in three dimensional space is opposite.

Then, the FEOL is performed. Specifically, as illustrated in FIG. 21A, a mask 51 having pattern grooves 52 is formed on the surface (front surface) of the semiconductor substrate SB by performing a mask formation process such as photolithography. The mask 51 can be configured as a hard mask made of an insulating material such as SiN (silicon nitride) or SiO₂ (silicon oxide). After that, an ion implantation process (implant process) is performed to form pixel separation portions 20 (vertical portions 20a) that extend in the depth direction Dh at portions of the semiconductor substrate SB exposed through the pattern grooves 52.

After that, as illustrated in FIG. 21B, a mask formation process and an ion implantation process are performed to form pixel separation portions 20 (horizontal portions 20b) that extend in the width direction Dw in the semiconductor substrate SB through pattern grooves 52 of a mask 51 formed on the surface of the semiconductor substrate SB. The mask 51 used in this step may be obtained by additionally forming the pattern grooves 52 on the mask 51 (see FIG. 21A) used to form the vertical portions 20a, or may be formed as a new mask after removing the mask 51 used to form the vertical portions 20a.

After that, as illustrated in FIG. 21C, a mask formation process and an ion implantation process are performed to form pixel separation portions 20 (second vertical portions 20e) that extend in the depth direction Dh in the semiconductor substrate SB through pattern grooves 52 of a mask 51 formed on the surface of the semiconductor substrate SB. The mask 51 used in this step is formed as a new mask after removing the mask 51 (see FIG. 21B) used to form the horizontal portions 20b.

After that, as illustrated in FIG. 21D, a mask formation process and an ion implantation process are performed to form pixel separation portions 20 (horizontal portions 20d) that extend in the width direction Dw in the semiconductor substrate SB through pattern grooves 52 of a mask 51 formed on the surface of the semiconductor substrate SB. The mask 51 used in this step may be obtained by additionally forming the pattern grooves 52 on the mask 51 (see FIG. 21C) used to form the second vertical portions 20e, or may be formed as a new mask after removing the mask 51 used to form the second vertical portions 20e.

After that, as illustrated in FIG. 21E, a mask formation process and an ion implantation process are performed to form pixel separation portions 20 (first vertical portions 20c) that extend in the depth direction Dh in the semiconductor substrate SB through pattern grooves 52 of a mask 51 formed on the surface of the semiconductor substrate SB. The mask 51 used in this step is formed as a new mask after removing the mask 51 (see FIG. 21D) used to form the horizontal portions 20d. After this step is completed, the mask 51 is removed from the semiconductor substrate SB.

After the above-described FEOL (FIGS. 21A to 21E) is completed, a substrate formation process such as epitaxial growth is performed to apply a new substrate thin film to the front surface side of the semiconductor substrate SB. FIG. 22A illustrates an additional boundary surface S1 that is a boundary surface (e.g., an epitaxial growth surface) between the surface (front surface) of the semiconductor substrate SB before the new substrate thin film is applied and the new substrate thin film. Then, vertical electrodes 22, charge holding portions 21, second light-shielding members 32, and pixel separation portions 20 (vertical portions 20a and covering portions 20f) are formed in the substrate thin film portion.

After that, the BEOL is performed. Specifically, as illustrated in FIG. 22A, a deposition process and a mask formation process are performed to deposit a deposited film 55 on the surface (back surface) of the semiconductor substrate SB and form a mask 56 having pattern grooves 57 on the deposited film 55. Then, dry etching is performed to form vertical grooves 58 that extend in the depth direction Dh in exposed portions of the deposited film 55 and the semiconductor substrate SB corresponding to the pattern grooves 57. The length of the vertical groove 58 in the depth direction Dh is determined according to the length of the first light-shielding portion 31a (see FIG. 4) in the depth direction Dh.

After the mask 56 is removed from the semiconductor substrate SB, a deposition process is performed to fill the vertical grooves 58 with etching stoppers 59, as illustrated in FIG. 22B. The etching stopper 59 may be a part of the first light-shielding portion 31a described above (see FIG. 4), or may be provided separately from the first light-shielding portion 31a. Prior to forming the etching stoppers 59, the deposited film 55 may or may not be removed from the semiconductor substrate SB.

After that, as illustrated in FIG. 22C, a mask formation process and dry etching are performed to form vertical grooves 60 that extend in the depth direction Dh at exposed portions of the semiconductor substrate SB corresponding to the pattern grooves 57 of the mask 56. The vertical groove 60 is provided at a position adjacent to the etching stopper 59 in the width direction Dw, and the etching stopper 59 is exposed to the vertical groove 60.

After the mask 56 is removed from the semiconductor substrate SB, wet etching is performed to form horizontal grooves 61 that extend in the width direction Dw from the bottoms of the vertical grooves 60 in the semiconductor substrate SB, as illustrated in FIG. 22D. At this time, since the etching stoppers 59 stop the progress of the wet etching, the wet etching proceeds in the <110> direction (to the right in FIG. 22D).

For example, an alkaline aqueous solution can be used as the etching solution used for the wet etching for the <110> direction of the semiconductor substrate SB. The etching stoppers 59 can be formed of a material that exhibits etching resistance against such an alkali aqueous solution (e.g., a crystal defect structure with an impurity element such as boron (B) or hydrogen ions injected, an insulator such as an oxide, or the like).

Here, crystal anisotropic etching is performed using the property of the semiconductor substrate SB in which the etching rate varies depending on the (111) plane orientation. Specifically, in the semiconductor substrate SB with a plane index of (111), the etching rate in the <110> direction is sufficiently higher than the etching rate in the <111> direction (downward direction in FIG. 22D). Therefore, in the wet etching described above, etching proceeds in the X direction while etching hardly proceeds in the Z direction. The distance that wet etching proceeds in the <110> direction can be adjusted by changing the etching processing time.

After that, as illustrated in FIG. 22E, a deposition process is performed to embed light-shielding metal bodies 62 in the vertical grooves 60 and the horizontal grooves 61. The light-shielding metal bodies 62 embedded in the vertical grooves 60 form the first light-shielding portions 31a described above (see FIG. 4). The light-shielding metal bodies 62 embedded in the horizontal grooves 61 form the second light-shielding portions 31b described above (see FIG. 4). Accordingly, the length of the vertical groove 60 in the depth direction Dh is determined according to the length of the first light-shielding portion 31a in the depth direction Dh. The length of the horizontal groove 61 in the width direction Dw is determined according to the length of the second light-shielding portion 31b in the width direction Dw.

After that, as illustrated in FIG. 22F, a mask formation process and dry etching are performed to form vertical grooves 63 that extend in the depth direction Dh at exposed portions of the semiconductor substrate SB corresponding to the pattern grooves 57 of the mask 56. The vertical groove 63 extends into the first vertical portion 20c of the pixel separation portion 20.

After the mask 56 is removed from the semiconductor substrate SB, a deposition process is performed to fill the vertical grooves 63 with the light-shielding metal bodies 64, as illustrated in FIG. 22G. The light-shielding metal bodies 64 embedded in the vertical grooves 63 form the third light-shielding portions 31c described above (see FIG. 4). Accordingly, the length of the vertical groove 63 in the depth direction Dh is determined according to the length of the third light-shielding portion 31c in the depth direction Dh.

After that, as illustrated in FIG. 22H, a removal process such as chemical mechanical polishing (CMP) or wet etching is performed to remove the etching stoppers 59, the light-shielding metal bodies 62, and the light-shielding metal bodies 64 from the back surface of the semiconductor substrate SB.

By performing the above-described series of manufacturing processes (FIGS. 21A to 22H), the semiconductor substrate SB used in the solid-state imaging element 10 is manufactured. After that, the color filter CF and the light-receiving lens LNS are arranged on the semiconductor substrate SB, thereby manufacturing the solid-state imaging element 10 (see FIG. 4).

The solid-state imaging element 10 may include portions/members other than the portions/members described above. For example, by arranging a solid charge film having a negative fixed charge on the back surface (light-receiving surface) of the semiconductor substrate SB, it is possible to prevent dark current from being generated due to the interface level of the back surface.

Next, a more specific example of a method of manufacturing the first light-shielding portion 31a and the second light-shielding portion 31b will be described.

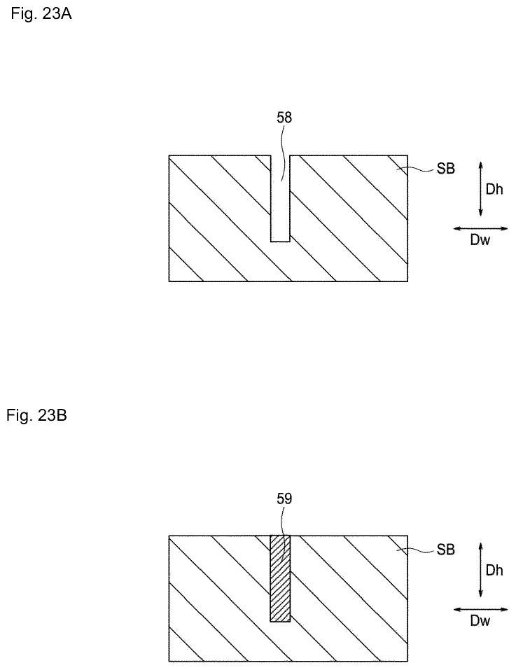

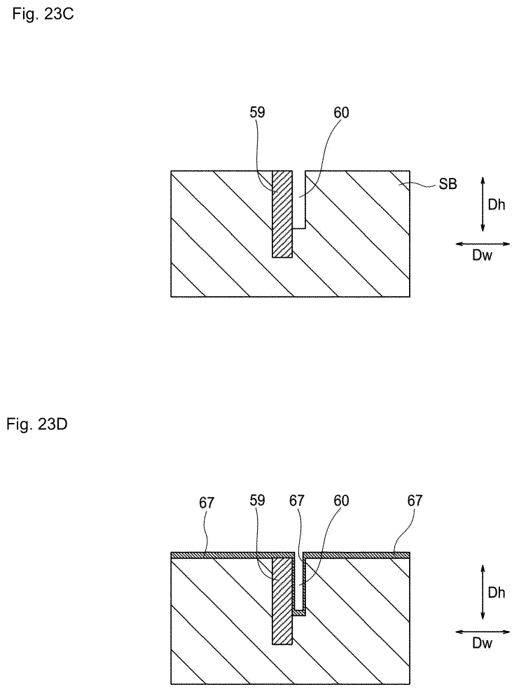

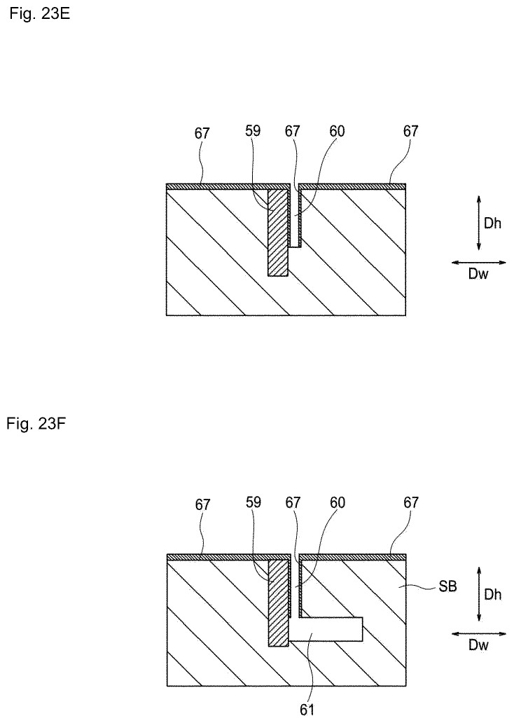

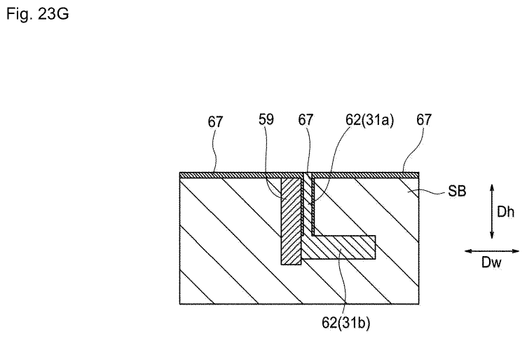

FIGS. 23A to 23G are cross-sectional views illustrating an example of the method of manufacturing the first light-shielding portion 31a and the second light-shielding portion 31b. In FIGS. 23A to 23G, illustration of the pixel separation portion 20 and others are omitted.

First, a vertical groove 58 is formed in a semiconductor substrate SB by dry etching (FIG. 23A), and an etching stopper 59 is embedded in the vertical groove 58 (FIG. 23B).

After that, a vertical groove 60 is formed by dry etching at a position adjacent to the etching stopper 59 in the width direction Dw (FIG. 23C), and a side wall 67 is applied to the surface of the semiconductor substrate SB that defines the vertical groove 60 (FIG. 23D). In the example illustrated in FIG. 23D, the side wall 67 is also formed on the upper surface of the semiconductor substrate SB. The side wall 67 can be made of an insulating film made of SiN or SiO₂, for example.

After that, a part of the side wall 67 is removed by dry etching to expose a portion of the semiconductor substrate SB that defines the bottom of the vertical groove 60 from the side wall 67 (FIG. 23E). The side wall 67 that covers portions that define the sides of the vertical groove 60 remain even after the dry etching performed in this step.

After that, wet etching is performed on the exposed portion to form a horizontal groove 61 in the semiconductor substrate SB (FIG. 23F). The wet etching performed in this step proceeds in the width direction Dw starting from the exposed portion of the semiconductor substrate SB. At this time, since the etching stopper 59 acts as a wet etching stopper as described above, the wet etching proceeds in the <110> direction (to the right in FIG. 23F). The side wall 67 acts as a mask for wet etching, and the portions of the semiconductor substrate SB that are covered by the side wall 67 are not wet etched.

After that, a light-shielding metal body 62 is embedded in the horizontal groove 61 (FIG. 23G). In FIG. 23G, the etching stopper 59 and the light-shielding metal body 62 are given different hatching, but the etching stopper 59 and the light-shielding metal body 62 may have the same composition or different compositions.

As described above, by providing the etching stopper 59 in manufacturing the solid-state imaging element 10, the horizontal groove 61 and the light-shielding metal body 62 (particularly the portion corresponding to the second light-shielding portion 31b) can be formed only in the predetermined width direction Dw.

### [Example of Application to Electronic Device]

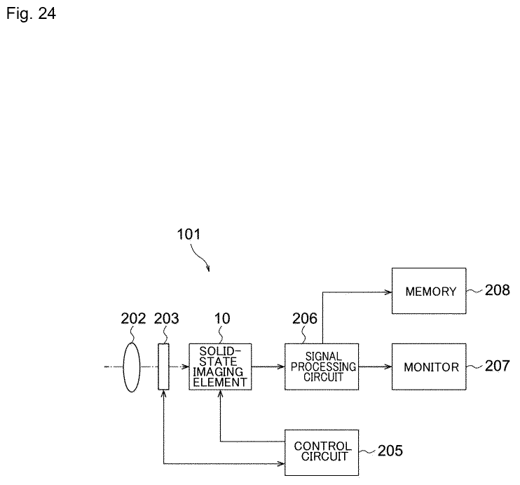

FIG. 24 is a block diagram illustrating a configuration example of the imaging device 101 as an electronic device to which the present technology is applied.

The imaging device 101 illustrated in FIG. 24 includes an optical system 202, a shutter device 203, a solid-state imaging element 10, a control circuit 205, a signal processing circuit 206, a monitor 207, and a memory 208, and can capture still images and moving images.

The optical system 202 includes one or more lenses, and guides light (incident light) from a subject to the solid-state imaging element 10, and forms an image on the light-receiving surface of the solid-state imaging element 10.

The shutter device 203 is arranged between the optical system 202 and the solid-state imaging element 10, and adjusts the light emission period and the light-shielding period for the solid-state imaging element 10 under the control of the control circuit 205.

The solid-state imaging element 10 can be configured as a package. The solid-state imaging element 10 accumulates signal charges for a certain period of time according to the light imaged on the light-receiving surface via the optical system 202 and the shutter device 203. The signal charges accumulated in the solid-state imaging element 10 are transferred according to a drive signal (timing signal) supplied from the control circuit 205.

The control circuit 205 outputs a drive signal that controls the transfer operation of the solid-state imaging element 10 and the shutter operation of the shutter device 203, and drives the solid-state imaging element 10 and the shutter device 203. The specific configuration and function of the control circuit 205 are not limited. For example, the control circuit 205 may include the system control unit 118, the clock module 115, and the horizontal drive unit 117, which are illustrated in FIG. 1.

The signal processing circuit 206 performs various types of signal processing on the signal charges output from the solid-state imaging element 10. An image (image data) obtained by the signal processing performed by the signal processing circuit 206 is supplied to the monitor 207 for display or supplied to the memory 208 for storage (recording). The specific configuration and function of the signal processing circuit 206 are not limited. For example, the signal processing circuit 206 may include the ramp wave module 113, the column signal processing unit 114, the data storage unit 116, and the signal processing unit 119, which are illustrated in FIG. 1.

The solid-state imaging element 10 and imaging device 101 described above can be used for any purpose. The imaging device 101 can be configured as, for example, a digital still camera or a digital video camera. The solid-state imaging element 10 may be installed in any electronic device other than the imaging device 101. The imaging device 101 may be configured as a camera device such as a digital camera that is directly operated by a user, or may be installed in various devices such as a mobile device (smartphone, tablet PC, etc.), a moving body (vehicle, etc.), and a medical device.

### <Example of Application to Moving Body>

The technology of the present disclosure (the present technology) can be applied to various products. For example, the technology according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

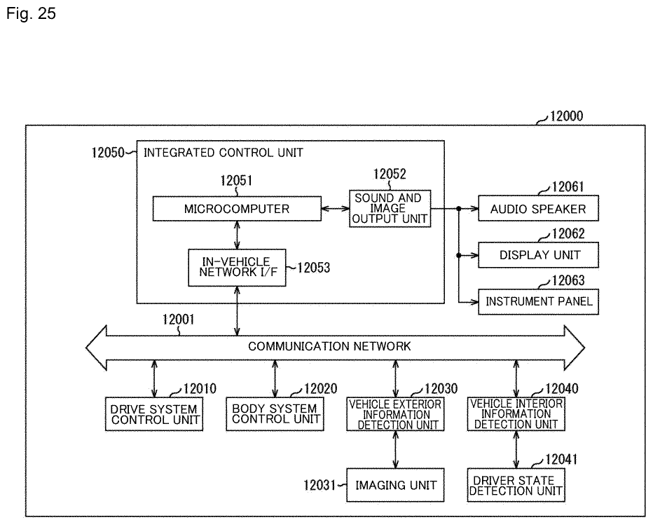

FIG. 25 is a block diagram illustrating an example of an overall configuration of a vehicle control system which is an example of a moving body control system to which the technology of the present disclosure can be applied.

The vehicle control system 12000 includes a plurality of electronic control units connected thereto via a communication network 12001. In the example illustrated in FIG. 25, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls operations of devices related to a drive system of a vehicle in accordance with various programs. For example, the drive system control unit 12010 functions as a control device for a driving force generation device for generating the driving force of the vehicle such as an internal combustion engine or a drive motor, a driving force transmission mechanism for transmitting the driving force to the wheels, a steering mechanism for adjusting the steering angle of the vehicle, a braking device for generating the braking force of the vehicle, or the like.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image outside the vehicle and receives the captured image. The vehicle exterior information detection unit 12030 may perform object detection processing or distance detection processing for people, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, by controlling the driving force generation device, the steering mechanism, the braking device, and the like on the basis of information regarding the vicinity of the vehicle acquired by the vehicle exterior information detection unit 12030 or the vehicle interior information detection unit 12040, the microcomputer 12051 can perform cooperative control for the purpose of automated driving or the like in which autonomous travel is performed without depending on an operation of the driver.

The microcomputer 12051 can also output a control command to the body system control unit 12020 based on the information outside the vehicle acquired by the vehicle exterior information detection unit 12030. For example, the microcomputer 12051 can perform cooperative control for the purpose of preventing glare such as controlling the headlamps to switch a high beam to a low beam according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example of FIG. 25, an audio speaker 12061, a display unit 12062, and an instrument panel 12063 are illustrated as examples of the output device. The display unit 12062 may include at least one of an on-board display and a head-up display, for example.

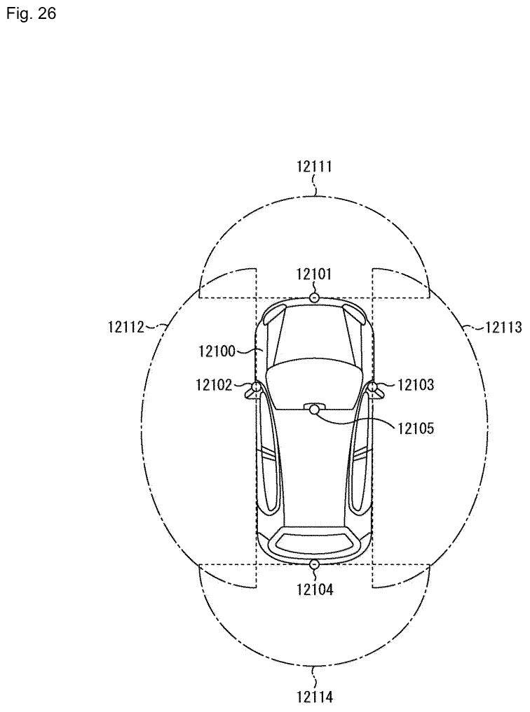

FIG. 26 is a diagram illustrating an example of the installation positions of imaging units 12031.

In FIG. 26, a vehicle 12100 includes imaging portions 12101, 12102, 12103, 12104, and 12105 as the imaging unit 12031.

The imaging units 12101, 12102, 12103, 12104, and 12105 are provided, for example, at positions such as a front nose, side mirrors, a rear bumper, a back door, and an upper part of a windshield in the occupant compartment of the vehicle 12100. The imaging unit 12101 provided on the front nose and the imaging unit 12105 provided on the upper part of the windshield in the occupant compartment mainly acquire images in front of the vehicle 12100. The imaging units 12102 and 12103 provided on the side mirrors mainly acquire images on the sides of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

FIG. 26 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (e.g., 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify three-dimensional object data relating to three-dimensional objects into that of a two-wheeled vehicle, an ordinary vehicle, a large vehicle, a pedestrian, an electric pole, and other three-dimensional objects and extract those three-dimensional objects based on the distance information obtained from the imaging units 12101 to 12104 and use the extracted three-dimensional objects for automatic avoidance of obstacles. For example, the microcomputer 12051 identifies obstacles around the vehicle 12100 as obstacles that are visible to the driver of the vehicle 12100 and obstacles that are difficult to view. Then, the microcomputer 12051 determines a collision risk indicating the degree of risk of collision with each obstacle, and when the collision risk is equal to or greater than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared light. For example, the microcomputer 12051 can recognize a pedestrian by determining whether there is a pedestrian in captured images of the imaging units 12101 to 12104. Such pedestrian recognition is performed, for example, through a procedure of extracting feature points in the images captured by the imaging units 12101 to 12104 as infrared cameras and a procedure of performing pattern matching processing on a series of feature points indicating an outline of an object to determine whether or not the object is a pedestrian. When the microcomputer 12051 determines that there is a pedestrian in the captured images of the imaging units 12101 to 12104, and the pedestrian is recognized, the sound and image output unit 12052 controls the display unit 12062 so that the recognized pedestrian is superimposed and displayed with a square contour line for emphasis. In addition, the sound and image output unit 12052 may control the display unit 12062 so that an icon indicating a pedestrian or the like is displayed at a desired position.

An example of a vehicle control system to which the technology according to the present disclosure can be applied has been described above. The technology according to the present disclosure can be applied to the imaging unit 12031 (imaging units 12101, 12102, 12103, 12104, 12105) and/or the driver state detection unit 12041 among the configurations described above. Specifically, the imaging unit 12031 (imaging units 12101, 12102, 12103, 12104, 12105) and/or the driver state detection unit 12041 may include the solid-state imaging element 10 and the imaging device 101 described above. By applying the technology according to the present disclosure to a moving body in this way, it is possible to effectively reduce PLS noise and suppress obstruction of the flow of electrons in the photoelectric conversion portion 15.

### <Example of Application to Endoscopic Surgery System>

The technology according to the present disclosure (the present technology) can be applied to various products. For example, the technology according to the present disclosure may be applied to an endoscopic surgery system.

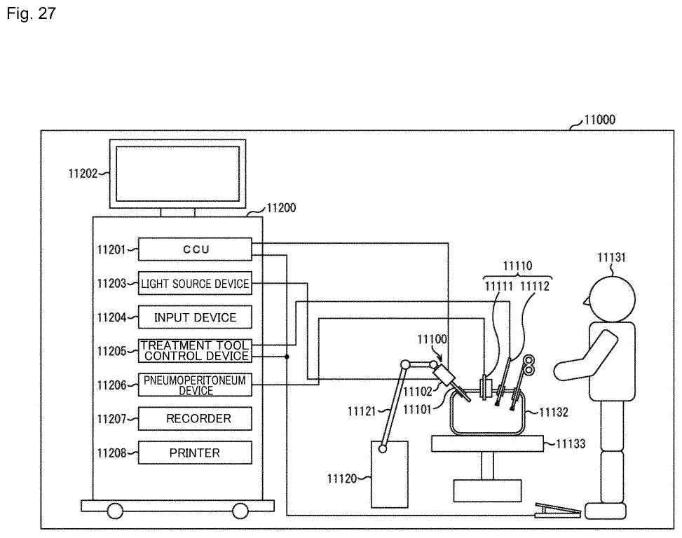

FIG. 27 is a diagram illustrating an example of a schematic configuration of an endoscopic surgery system to which the technology according to the present disclosure (the present technology) can be applied.

FIG. 27 illustrates a state where a surgeon (doctor) 11131 is performing a surgical operation on a patient 11132 on a patient bed 11133 by using the endoscopic surgery system 11000. As illustrated, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic surgery.

The endoscope 11100 includes a lens barrel 11101 of which a region having a predetermined length from a distal end thereof is inserted into a body cavity of the patient 11132, and a camera head 11102 connected to a proximal end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is configured of a central processing unit (CPU), a graphics processing unit (GPU), and the like and comprehensively controls the operation of the endoscope 11100 and a display device 11202. The CCU 11201 also receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 includes, for example, a light source such as a light emitting diode (LED) and supplies the endoscope 11100 with radiation light when imaging a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls driving of the energized treatment tool 11112 for cauterization or incision of a tissue, sealing of blood vessel, or the like. A pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the radiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter in the imaging element.

Further, driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of radiation light (i.e., white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

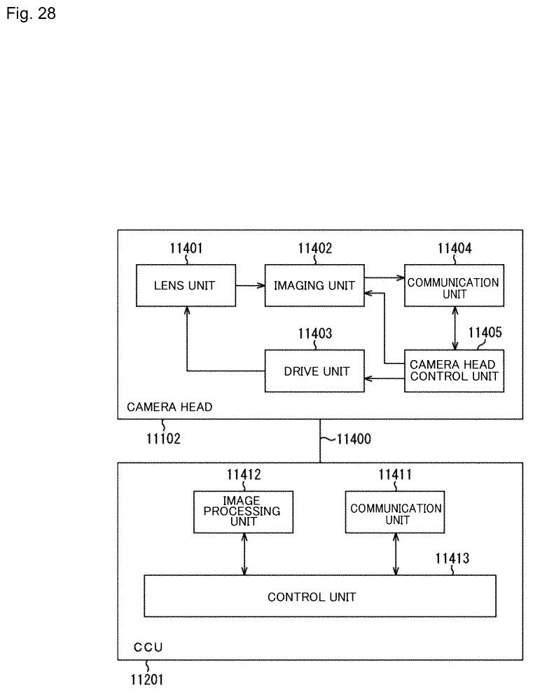

FIG. 28 is a block diagram illustrating an example of a functional configuration of the camera head 11102 and CCU 11201 illustrated in FIG. 27.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a distal end of the lens barrel 11101 is guided to the camera head 11102 and is incident on the lens unit 11401. The lens unit 11401 is configured in combination of a plurality of lenses including a zoom lens and a focus lens.

The imaging unit 11402 is constituted by an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, a surgeon 11131 can ascertain the depth of biological tissues in the surgical site more accurately. When the imaging unit 11402 is configured in a multi-plate type, a plurality of systems of lens units 11401 may be provided in correspondence to the image sensors.

The imaging unit 11402 does not necessarily have to be provided in the camera head 11102. For example, the imaging unit 11402 may be provided immediately after the objective lens inside of the lens barrel 11101.

The drive unit 11403 is constituted by an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the control signal to the camera head control unit 11405. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 is constituted by a communication device for transmitting or receiving various information to or from the camera head 11102. The communication unit 11411 receives an image signal transmitted via the transmission cable 11400 from the camera head 11102.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site, or the like. For example, the control unit 11413 generates a control signal for controlling driving of the camera head 11102.

The control unit 11413 also causes the display device 11202 to display the captured image of the surgical site or the like on the basis of the image signal subjected to the image processing in the image processing unit 11412. In doing so, the control unit 11413 may recognize various objects in the captured image using various image recognition techniques. For example, the control unit 11413 can recognize a surgical instrument such as forceps, a specific biological site, bleeding, mist or the like at the time of use of the energized treatment tool 11112, or the like by detecting a shape, a color, or the like of an edge of an object included in the captured image. When the control unit 11413 causes the captured image to be displayed on the display device 11202, the control unit 11413 may cause various types of surgery support information to be superimposed on the image of the surgical site and displayed using a result of the recognition. By displaying the surgery support information in a superimposed manner and presenting it to the surgeon 11131, a burden on the surgeon 11131 can be reduced, and the surgeon 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of an endoscopic surgery system to which the technology according to the present disclosure can be applied has been described above. The technology according to the present disclosure can be applied to the camera head 11102 among the components described above. Specifically, the camera head 11102 (particularly the imaging unit 11402) can include the solid-state imaging element 10 and the imaging device 101 described above. By applying the technology according to the present disclosure to the camera head 11102, it is possible to effectively reduce PLS noise and suppress obstruction of the flow of electrons in the photoelectric conversion portion 15.

Although the endoscopic surgery system has been described as an example herein, the technology according to the present disclosure may be applied to other, for example, a microscopic surgery system.

### Modification Example

The technology of the present disclosure is not limited to the embodiments described above.

The actual color filter portions including the first-type to third-type color filter portions described above may vary depending on the type, arrangement, and number of types of the color filter portions included in the color filter CF. For example, in a case where the color filter CF does not include the R filter portion CFr, the color filter portion that transmits light in a wavelength range on the longest wavelength side can be treated as the first-type color filter portion. Specifically, the vertical electrode 22 of the first-type pixel to which the color filter portion that transmits light in the wavelength range on the longest wavelength side is assigned may be covered by the second light-shielding portion 31b. Also in this case, at least a part of the pixel separation portion 20 facing the second light-shielding portion 31b in the width direction Dw may be disposed at a position that does not overlap with the first-type color filter portion but overlaps with the second-type color filter portion when viewed from above in the depth direction Dh.

It should be noted that the embodiments and modification examples disclosed herein are merely illustrative in all respects and should not be construed as limiting the present disclosure. The above-described embodiments and modification examples can be omitted, substituted, and modified in various ways without departing from the scope and spirit of the appended claims. For example, the above-described embodiments and modification examples may be wholly or partially combined, and any combination of an embodiment other than above-described embodiments and the above-described embodiments or modifications may be made. In addition, the advantageous effects of the present disclosure as described herein are merely exemplary and other advantageous effects may be produced.

Further, the technical category in which the above-described technical ideas are embodied is not limited. For example, the above-described technical ideas may be embodied by a computer program for causing a computer to execute one or more procedures (steps) included in the method of manufacturing or using the device described above. The above-described technical ideas may be embodied by a non-transitory computer-readable recording medium in which such a computer program is recorded.

### [Supplementary Notes]

The present disclosure can also be configured as follows:

### [Item 1]

A solid-state imaging element including:
a substrate with a plurality of pixels arranged; and
a color filter that covers the substrate,
wherein each of the plurality of pixels includes
a photoelectric conversion portion that is partitioned by a pixel separation portion, a charge holding portion that holds a charge, and
a charge transfer portion that transfers the charge generated in the photoelectric conversion portion to the charge holding portion,
the color filter includes a first-type color filter portion, and a second-type color filter portion that transmits light in a wavelength range on a shorter wavelength side than a light transmission wavelength range of the first-type color filter portion, the plurality of pixels include a first-type pixel to which the first-type color filter portion is assigned, and a second-type pixel to which the second-type color filter portion is assigned,
the pixel separation portion is provided with a first light-shielding member that is disposed closer to the color filter than the charge transfer portion is,
the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and
at least a part of a portion of the pixel separation portion facing the second light-shielding portion in the width direction is disposed at a position that does not overlap with the first-type color filter but overlaps with the second-type color filter when viewed from above in the depth direction.

### [Item 2]

The solid-state imaging element according to item 1, wherein
the color filter further includes a third-type color filter portion that transmits light in a wavelength range shorter than that of the second-type color filter portion, and
the plurality of pixels further include a third-type pixel to which a third-type color filter portion is assigned.

### [Item 3]

The solid-state imaging element according to item 1 or 2, wherein
the first-type color filter portion is an R color filter portion, and
the second-type color filter portion is a G color filter portion.

### [Item 4]

The solid-state imaging element according to any one of items 1 to 3, wherein the color filter has a Bayer array.

### [Item 5]

The solid-state imaging element according to any one of items 1 to 3, wherein the color filter has a Quad-Bayer array.

### [Item 6]

The solid-state imaging element according to any one of items 1 to 5, wherein
the first light-shielding member includes a third light-shielding portion that extends in the depth direction, and a fourth light-shielding portion that extends in the width direction and is disposed at a position that partially overlaps with both of the photoelectric conversion portion of the first-type pixel and the photoelectric conversion portion of the second-type pixel when viewed from above in the depth direction, and
the fourth light-shielding portion is disposed at a different position from the second light-shielding portion in the depth direction and between the photoelectric conversion portion of the first-type pixel and the photoelectric conversion portion of the second-type pixel.

### [Item 7]

The solid-state imaging element according to any one of items 1 to 6, including a second light-shielding member that covers the charge holding portion.

### [Item 8]

The solid-state imaging element according to any one of items 1 to 7, including a third light-shielding member that is disposed closer to the color filter than the charge transfer portion is and extends in the depth direction between the photoelectric conversion portion of the first-type pixel and the photoelectric conversion portion of the second-type pixel.

### [Item 9]

The solid-state imaging element according to any one of items 1 to 8, wherein a distance in the depth direction between a light incident surface of the photoelectric conversion portion on which light from the color filter is incident and the charge transfer portion is 5.0 μm or more.

### [Item 10]

An electronic device including a solid-state imaging element, wherein
the solid-state imaging element includes
a substrate with a plurality of pixels arranged, and
a color filter that covers the substrate,
each of the plurality of pixels includes
a photoelectric conversion portion that is partitioned by a pixel separation portion, a charge holding portion that holds a charge,
a charge transfer portion that transfers the charge generated in the photoelectric conversion portion to the charge holding portion, and
a first light-shielding member that is provided in the pixel separation portion and is disposed closer to the color filter than the charge transfer portion is,
the color filter includes a first-type color filter portion, and a second-type color filter portion that transmits light in a wavelength range on a shorter wavelength side than a light transmission wavelength range of the first-type color filter portion, the plurality of pixels include a first-type pixel to which the first-type color filter portion is assigned, and a second-type pixel to which the second-type color filter portion is assigned,
the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and
at least a part of a portion of the pixel separation portion facing the second light-shielding portion in the width direction is disposed at a position that does not overlap with the first-type color filter but overlaps with the second-type color filter when viewed from above in the depth direction.

### REFERENCE SIGNS LIST

10 Solid-state imaging element
15 Photoelectric conversion portion
20 Pixel separation portion
20a Vertical portion
20b Horizontal portion
20c First vertical portion
20d Horizontal portion
20e Second vertical portion
20f Covering portion
21 Charge holding portion
22 Vertical electrode
31 First light-shielding member
31a First light-shielding portion
31b Second light-shielding portion
31c Third light-shielding portion
31d Fourth light-shielding portion
31e Fifth light-shielding portion
32 Second light-shielding member
33 Third light-shielding member
51 Mask
52 Pattern groove
55 Deposited film
56 Mask
57 Pattern groove
58 Vertical groove
59 Etching stopper
60 Vertical groove
61 Horizontal groove
62 Light-shielding metal body
63 Vertical groove
64 Light-shielding metal body
67 Side wall
101 Imaging device
111 Pixel array unit
112 Vertical drive unit
113 Ramp wave module
114 Column signal processing unit
115 Clock module
116 Data storage unit
117 Horizontal drive unit
118 System control unit
119 Signal processing unit
121 Sensor pixel
121R R pixel
121G G pixel
121B B pixel
122 Pixel drive line
123 Vertical signal line
CF Color filter
CFr R filter portion
CFg G filter portion
CFb B Filter portion
Dh Depth direction
Dw Width direction
L1 Distance
LNS Light-receiving lens
S1 Additional boundary surface
SB Semiconductor substrate

1. A solid-state imaging element comprising:
a substrate with a plurality of pixels arranged; and
a color filter that covers the substrate,
wherein each of the plurality of pixels includes
a photoelectric conversion portion that is partitioned by a pixel separation portion,
a charge holding portion that holds a charge, and
a charge transfer portion that transfers the charge generated in the photoelectric conversion portion to the charge holding portion,
the color filter includes a first-type color filter portion, and a second-type color filter portion that transmits light in a wavelength range on a shorter wavelength side than a light transmission wavelength range of the first-type color filter portion,
the plurality of pixels include a first-type pixel to which the first-type color filter portion is assigned, and a second-type pixel to which the second-type color filter portion is assigned,
the pixel separation portion is provided with a first light-shielding member that is disposed closer to the color filter than the charge transfer portion is,
the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and
at least a part of a portion of the pixel separation portion facing the second light-shielding portion in the width direction is disposed at a position that does not overlap with the first-type color filter but overlaps with the second-type color filter when viewed from above in the depth direction.

2. The solid-state imaging element according to claim 1, wherein
the color filter further includes a third-type color filter portion that transmits light in a wavelength range shorter than that of the second-type color filter portion, and
the plurality of pixels further include a third-type pixel to which a third-type color filter portion is assigned.

3. The solid-state imaging element according to claim 1, wherein
the first-type color filter portion is an R color filter portion, and
the second-type color filter portion is a G color filter portion.

4. The solid-state imaging element according to claim 1, wherein the color filter has a Bayer array.

5. The solid-state imaging element according to claim 1, wherein the color filter has a Quad-Bayer array.

6. The solid-state imaging element according to claim 1, wherein
the first light-shielding member includes a third light-shielding portion that extends in the depth direction, and a fourth light-shielding portion that extends in the width direction and is disposed at a position that partially overlaps with both of the photoelectric conversion portion of the first-type pixel and the photoelectric conversion portion of the second-type pixel when viewed from above in the depth direction, and
the fourth light-shielding portion is disposed at a different position from the second light-shielding portion in the depth direction and between the photoelectric conversion portion of the first-type pixel and the photoelectric conversion portion of the second-type pixel.

7. The solid-state imaging element according to claim 1, comprising a second light-shielding member that covers the charge holding portion.

8. The solid-state imaging element according to claim 1, comprising a third light-shielding member that is disposed closer to the color filter than the charge transfer portion is and extends in the depth direction between the photoelectric conversion portion of the first-type pixel and the photoelectric conversion portion of the second-type pixel.

9. The solid-state imaging element according to claim 1, wherein a distance in the depth direction between a light incident surface of the photoelectric conversion portion on which light from the color filter is incident and the charge transfer portion is 5.0 μm or more.

10. An electronic device comprising a solid-state imaging element, wherein
the solid-state imaging element includes
a substrate with a plurality of pixels arranged, and
a color filter that covers the substrate,
each of the plurality of pixels includes
a photoelectric conversion portion that is partitioned by a pixel separation portion,
a charge holding portion that holds a charge,
a charge transfer portion that transfers the charge generated in the photoelectric conversion portion to the charge holding portion, and
a first light-shielding member that is provided in the pixel separation portion and is disposed closer to the color filter than the charge transfer portion is,
the color filter includes a first-type color filter portion, and a second-type color filter portion that transmits light in a wavelength range on a shorter wavelength side than a light transmission wavelength range of the first-type color filter portion,
the plurality of pixels include a first-type pixel to which the first-type color filter portion is assigned, and a second-type pixel to which the second-type color filter portion is assigned,
the first light-shielding member includes a first light-shielding portion that extends in a depth direction of the substrate, and a second light-shielding portion that extends in a width direction perpendicular to the depth direction and is disposed at a position that overlaps with the charge transfer portion of the first-type pixel when viewed from above in the depth direction, and
at least a part of a portion of the pixel separation portion facing the second light-shielding portion in the width direction is disposed at a position that does not overlap with the first-type color filter but overlaps with the second-type color filter when viewed from above in the depth direction.
